(19) United States
(12) Patent Application Publication
(10) Pub. No.: US 2026/0082631 A1
(43) Pub. Date: Mar. 19, 2026

(54) Bottom Insulation for Multigate Device

(71) Applicant: Taiwan Semiconductor Manufacturing Company, Ltd., Hsin-Chu (TW)

(72) Inventors: Ming-Heng TSAI, Taipei (TW); Jin-Aun NG, Hsinchu City (TW); Ta-Chun LIN, Hsinchu (TW); Chun-Sheng LIANG, Puyan Township (TW)

(21) Appl. No.: 18/885,274

(22) Filed: Sep. 13, 2024

(51) Int. Cl. H01L 29/423; H01L 21/8234; H01L 21/8238; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 64/021; H10D 84/0128; H10D 84/013; H10D 84/0135; H10D 84/0144; H10D 84/0167; H10D 84/017; H10D 84/0172; H10D 84/0181; H10D 84/038; H10D 84/85

(57) ABSTRACT

Multigate devices having bottom insulation and methods of fabrication thereof are disclosed herein. An exemplary bottom channel insulation structure includes a first insulation layer disposed over a substrate (e.g., an extension thereof) and a second insulation layer disposed over the first insulation layer. The first insulation layer has a first composition and a first length. The second insulation layer has a second composition that is different than the first composition and a second length that is greater than the first length. The first insulation layer is a bottom sacrificial layer of a set of sacrificial layers that are formed and subsequently replaced with a gate stack during fabrication of a multigate device. The bottom sacrificial layer is a dummy sacrificial layer because is not replaced with the gate stack, such that additional insulation is provided between the gate stack and the substrate and/or between source/drains.

### BACKGROUND

Recently, multigate devices, which have gates that extend, partially or fully, around a channel to provide access to the channel on at least two sides, have been introduced to improve gate control. Exemplary multigate devices include fin-like field effect transistors (FinFETs) and gate-all around (GAA) transistors, such as nanowire transistors. Multigate devices enable aggressive scaling down of integrated circuit (IC) technologies, maintaining gate control, and mitigating short-channel effects (SCEs), while seamlessly integrating with conventional IC manufacturing processes. As multigate devices continue to scale, advanced techniques are needed for optimizing multigate device reliability and/or performance.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a device having bottom insulation, in portion or entirety, according to various aspects of the present disclosure.

FIGS. 2-13 are cross-sectional views of a device, in portion or entirety, at various fabrication stages of the method in FIG. 1, according to various aspects of the present disclosure.

FIG. 14 is a cross-sectional view of the device of FIG. 13, in portion or entirety, according to various aspects of the present disclosure.

FIG. 15 is a cross-sectional view of a different configuration of the device of FIG. 13 and FIG. 14, in portion or entirety, that may be fabricated by the method in FIG. 1, according to various aspects of the present disclosure.

FIG. 16 is a cross-sectional view of another device, in portion or entirety, that may be fabricated by the method in FIG. 1, according to various aspects of the present disclosure.

### DETAILED DESCRIPTION

The present disclosure relates generally to multigate devices and methods of fabrication thereof, and more particularly, to leakage reduction for multigate devices.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +1-15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multigate devices include a gate structure that extends, partially or fully, around a channel region to provide access to a channel region on at least two sides. One such multigate device is the gate-all around (GAA) device, which includes channel layers (regions) that are vertically or horizontally stacked and suspended in a manner over a substrate that allows a gate stack to wrap around (or surround) and engage the channel layers. The channel layers extend between a source region and a drain region (e.g., epitaxial source/drains), and voltage can be applied to the gate stack, the source region, and/or the drain region to control a flow of current between the source region and the drain region. GAA devices can significantly increase contact area between the gate stack and the channel regions, which has been observed to decrease subthreshold swing (SS), decrease short channel effects (SCEs), increase drive current, and/or improve channel control compared to other multigate devices, such as FinFETs.

However, leakage current of GAA devices has arisen as a significant challenge as integrated circuit (IC) technology nodes scale (i.e., by increasing device density (i.e., the number of interconnected devices in a given chip area) and/or decreasing geometry size (i.e., dimensions and/or sizes of device features and/or spacings therebetween)). For example, a parasitic transistor can form between the gate stack, an elevated portion of the substrate (over which the channel layers and gate stack are disposed), and the epitaxial source/drains, and current may undesirably flow/leak through the elevated portion of the substrate between the epitaxial source/drains. Since the gate stack wraps the elevated portion of the substrate in a conventional GAA device as opposed to surrounding it like the channel layers, the gate stack's control of the off-state leakage current in the elevated portion of the substrate is limited to three sides (e.g., tri-gate control), which has proved insufficient as IC technology nodes scale and has been observed to induce and/or exacerbate drain-induced-barrier-lowering (DIBL) in GAA devices.

The present disclosure thus proposes a bottom isolation technique (which can also be referred to as a substrate isolation technique and/or a mesa isolation technique) that significantly reduces leakage current through an underlying substrate (e.g., mesa thereof) with minimal effect on other electrical characteristics of a GAA device, such as channel resistance. For example, bottom channel insulation structures, alone or in combination with bottom source/drain insulation structures are disclosed herein for multigate devices (e.g., GAA devices) that may reduce and/or eliminate leakage current. An exemplary bottom channel insulation structure may include two insulation layers, one of which is a dummy sacrificial layer. The dummy sacrificial layer belongs to a set of sacrificial layers that are formed in a channel region and subsequently replaced with a gate during fabrication of the multigate device. The dummy sacrificial layer is not replaced during the gate replacement process, and instead, remains between an insulation layer and the underlying substrate (e.g., mesa thereof) to provide additional insulation. Fabrication of the exemplary bottom channel insulation structure is seamlessly and easily integrated into existing multigate device fabrication processes. Details of the proposed bottom insulation structures and methods of fabrication thereof are described further below. From the following description, it may be seen that multigate devices described in the present disclosure offer advantages over conventional multigate devices. It is understood, however, that other embodiments may offer additional advantages, and not all advantages are necessarily disclosed herein, and that no particular advantage is required for all embodiments.

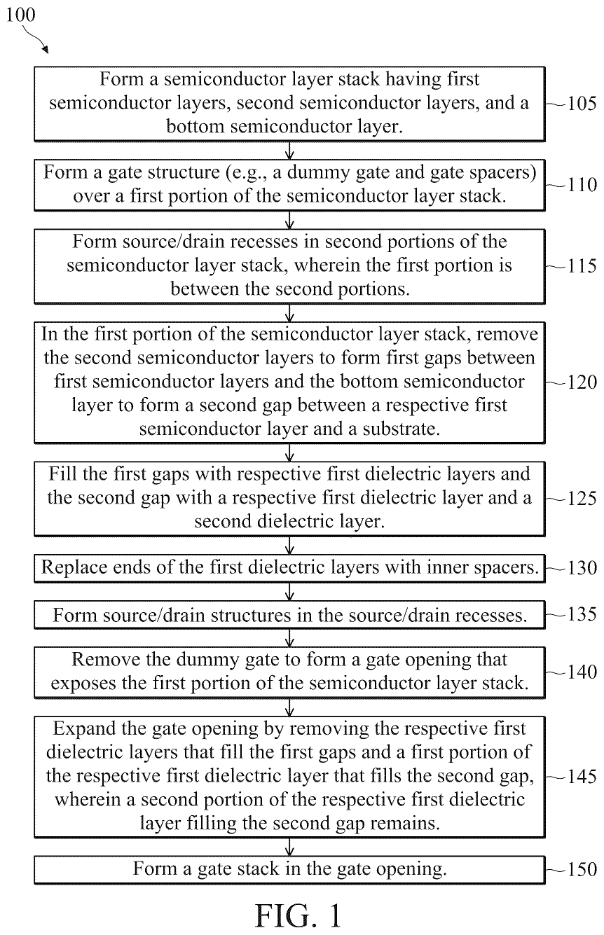

FIG. 1 is a flow chart of a method 100 for fabricating a multigate device, in portion or entirety, according to various aspects of the present disclosure. At block 105, method 100 includes forming a semiconductor layer stack over a substrate. The semiconductor layer stack includes first semiconductor layers, second semiconductor layers, and a bottom semiconductor layer. The first semiconductor layers and the second semiconductor layers have different compositions. The second semiconductor layers and the bottom semiconductor layer may have the same composition or different compositions. A thickness of the bottom semiconductor layer may be greater than a thickness of the second semiconductor layers. At block 110 and block 115, method 100 includes forming a gate structure (e.g., a dummy gate and gate spacers) over a first portion of the semiconductor layer stack and forming source/drain recesses in second portions of the semiconductor layer stack, respectively. The first portion may be disposed between the second portions. At block 120, method 100 includes, in the first portion of the semiconductor layer stack, removing the second semiconductor layers to form first gaps between the first semiconductor layers and removing the bottom semiconductor layer to form a second gap between a respective first semiconductor layer and the substrate (e.g., an extension thereof). A height of the first gaps may be less than a height of the second gap. At block 125, method 100 includes filling the first gaps with respective first dielectric layers and the second gap with a respective first dielectric layer and a second dielectric layer. At block 130, method 100 may include replacing ends of the first dielectric layers with inner spacers.

At block 135, method 100 includes forming source/drain structures in the source/drain recesses. The source/drain structures may include one or more doped semiconductor layers disposed over bottom source/drain insulation structures, which may include an insulation layer, alone or in combination with an undoped semiconductor layer. In some embodiments, a dielectric layer, such as an interlayer dielectric layer and/or a contact etch stop layer, is formed after forming source/drain structures at block 135 and before performing a gate replacement process (i.e., replacing the dummy gate with a metal gate) as described herein. At block 140, method 100 includes removing the dummy gate to form a gate opening that exposes the first portion of the semiconductor layer stack, which at this stage of fabrication may include the first semiconductor layers, the first dielectric layers, the second dielectric layer, and the inner spacers. At block 145, method 100 includes expanding the gate opening by removing the respective first dielectric layers that fill the first gaps and a portion of the respective first dielectric layer that fills the second gap. In other words, the second dielectric layer and a second portion of the respective first dielectric layer filling the second gap remain after expanding the gate opening. In some embodiments, the first portion of the respective first dielectric layer that fills the second gap is an upper portion thereof and the second portion of respective first dielectric layer that fills the second gap is a lower portion, and the second dielectric layer is disposed between the first portion and the second portion. The expanded gate opening exposes the first semiconductor layers. At block 150, method 100 includes forming a gate stack in the gate opening. The gate stack may engage the first semiconductor layers, and the gate stack may include a gate dielectric and a gate electrode. A portion of the gate stack may be disposed between the respective first semiconductor layer and the second dielectric layer. Additional processing is contemplated by the present disclosure. Additional steps may be provided before, during, and after method 100, and some of the steps described may be moved, replaced, or eliminated for additional embodiments of method 100. The discussion that follows illustrates various embodiments of multigate devices that may be fabricated according to method 100.

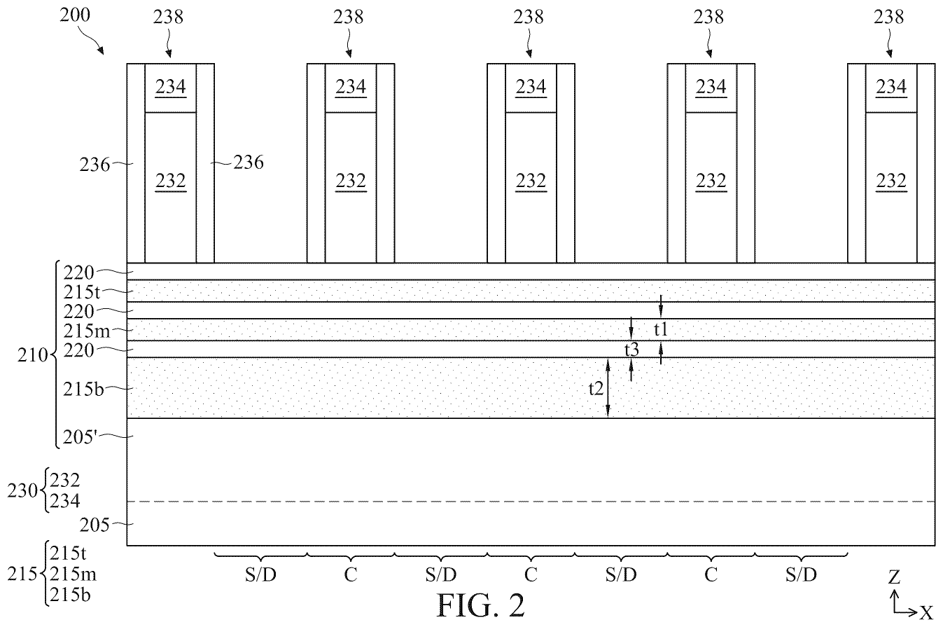

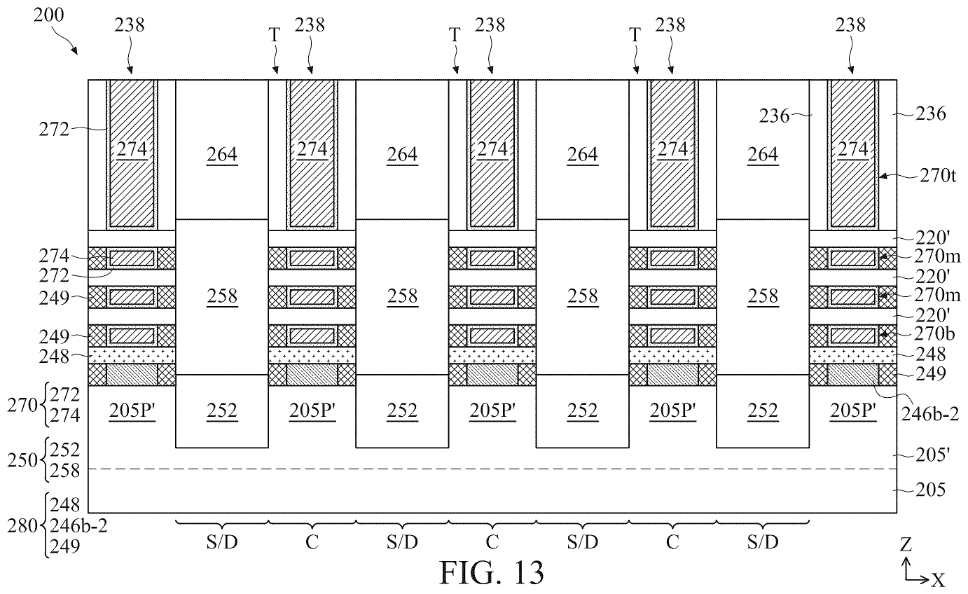

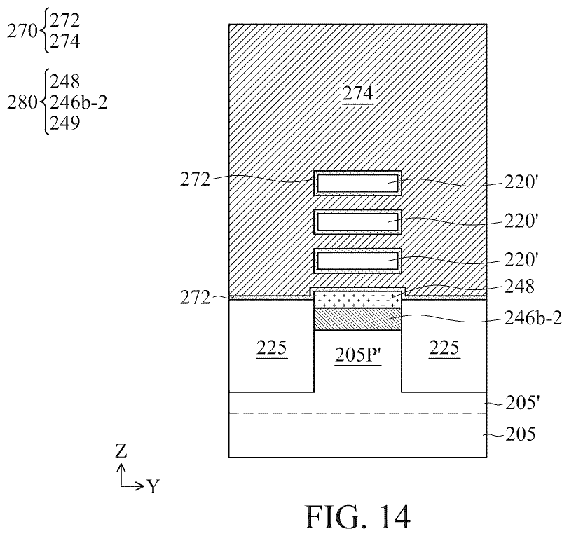

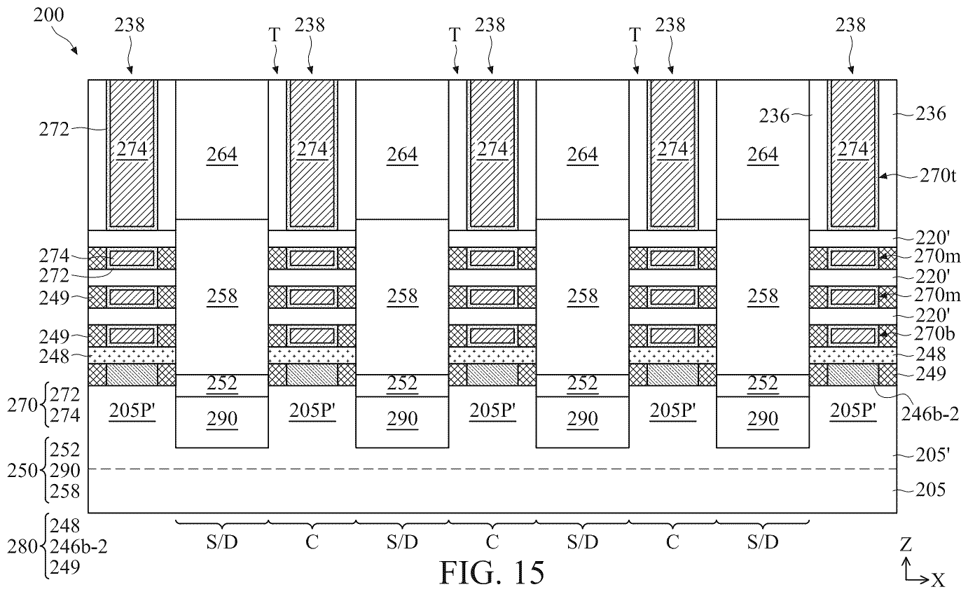

FIGS. 2-13 are cross-sectional views of a device 200, in portion or entirety, at various fabrication stages (such as those associated with method 100 in FIG. 1) according to various aspects of the present disclosure. FIG. 14 is a cross-sectional view of device 200 along line A-A of FIG. 13, in portion or entirety, according to various aspects of the present disclosure. After undergoing processing associated with FIGS. 2-13, device 200 may include at least one GAA transistor (i.e., a transistor having a gate that at least partially surrounds a suspended channel(s) (for example, a nanowire(s), a nanosheet(s), a nanobar(s), or the like) that extends between source/drains). In some embodiments, device 200 includes p-type GAA transistors, n-type GAA transistors, or combinations thereof. In some embodiments, device 200 includes a complementary metal-oxide semiconductor (CMOS) transistor (e.g., an n-type GAA transistor and a p-type transistor). Device 200 may be included in a microprocessor, a memory, other IC device, or combinations thereof. In some embodiments, device 200 is a portion of an IC chip, a system on chip (SoC), or portion thereof, that includes various passive electronic devices and/or active electronic devices, such as resistors, capacitors, inductors, diodes, p-type field effect transistors (PFETs), n-type FETs (NFETs), metal-oxide-semiconductor FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof. FIG. 15 is a cross-sectional view of a different configuration of device 200, in portion or entirety, after undergoing processing associated with method 100 in FIG. 1, according to various aspects of the present disclosure. FIGS. 2-15 have been simplified for the sake of clarity to better understand the inventive concepts of the present disclosure. Additional features may be added in device 200, and some of the features described below may be replaced, modified, or eliminated in other embodiments of device 200.

Referring to FIG. 2, device 200 includes a substrate 205 and a multilayer stack 210 disposed thereover. Multilayer stack 210 may include sacrificial layers 215, semiconductor layers 220, and a mesa 205′ (e.g., a patterned, projecting portion of substrate 205). Substrate 205 includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 205 is a silicon substrate. In some embodiments, substrate 205 is a semiconductor-on-insulator substrate, such as a silicon-on-insulator (SOI) substrate, a silicon germanium-on-insulator (SGOI) substrate, or a germanium-on-insulator (GOI) substrate. Substrate 205 (and mesa 205′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include combinations of p-type dopants and n-type dopants. The doped regions may be formed directly on and/or in substrate 205, for example, providing a p-well structure, an n-well structure, a dual-well structure, a raised structure, other suitable structure, or combinations thereof. In some embodiments, substrate 205 and/or mesa 205′, and semiconductor layers thereover, may include an n-well and/or a p-well.

A composition of sacrificial layers 215 is different than a composition of semiconductor layers 220 to achieve etch selectivity. For example, sacrificial layers 215 and semiconductor layers 220 include different materials, constituent atomic percentages, constituent weight percentages, other characteristics, or combinations thereof to achieve etch selectivity. In some embodiments, sacrificial layers 215 include silicon germanium and semiconductor layers 220 include silicon, and an etch rate of semiconductor layers 220 is different than an etch rate of sacrificial layers 215 to a given etchant. In some embodiments, sacrificial layers 215 and semiconductor layers 220 include the same material but with different constituent atomic percentages. For example, sacrificial layers 215 and semiconductor layers 220 may include silicon germanium, where sacrificial layers 215 and semiconductor layers 220 have different germanium atomic percentages. Constituent atomic percentages of the sacrificial layers 215 may be substantially the same. For example, sacrificial layers 215 may each include the same germanium concentration. Sacrificial layers 215 and semiconductor layers 220 may include any combination of semiconductor materials that provides desired etching selectivity, desired oxidation rate differences, and/or desired performance characteristics (e.g., materials that maximize current flow), including any of the semiconductor materials disclosed herein.

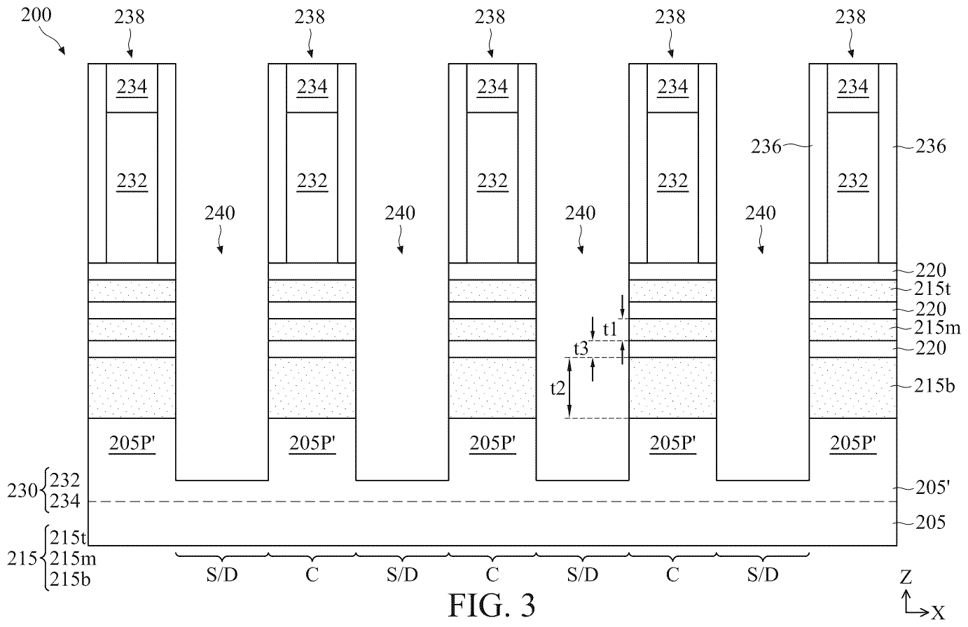

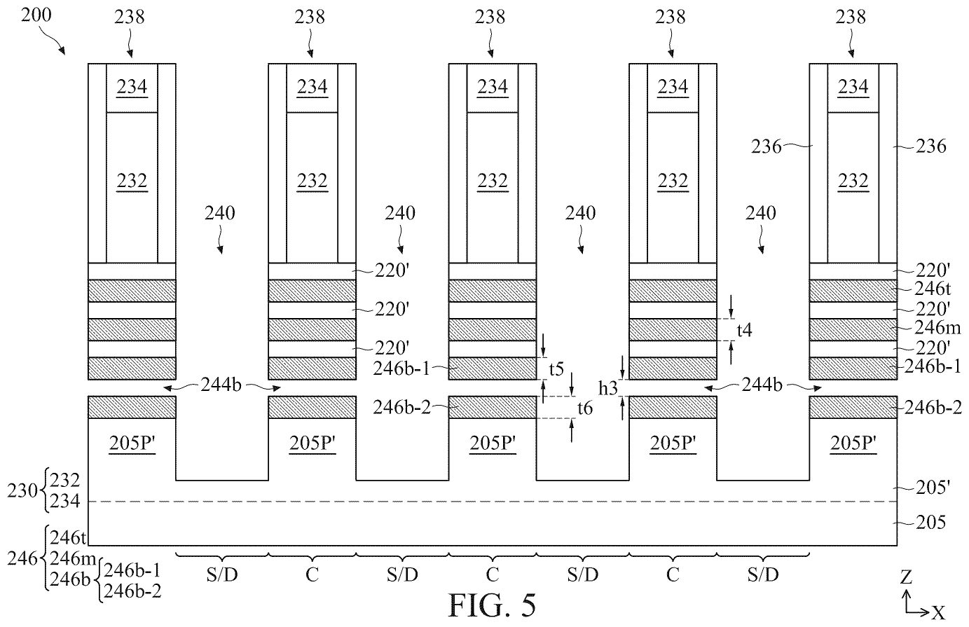

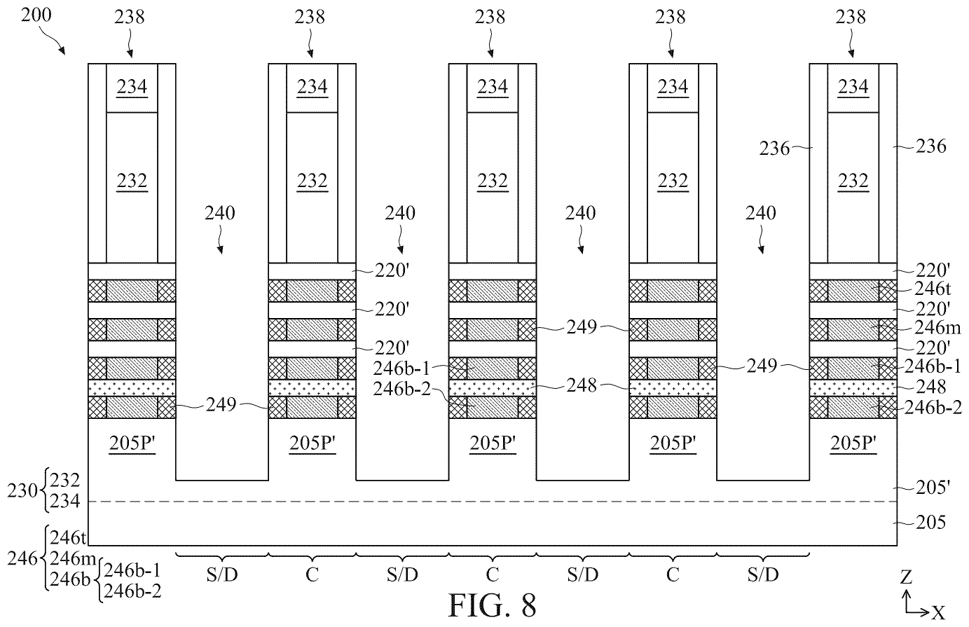

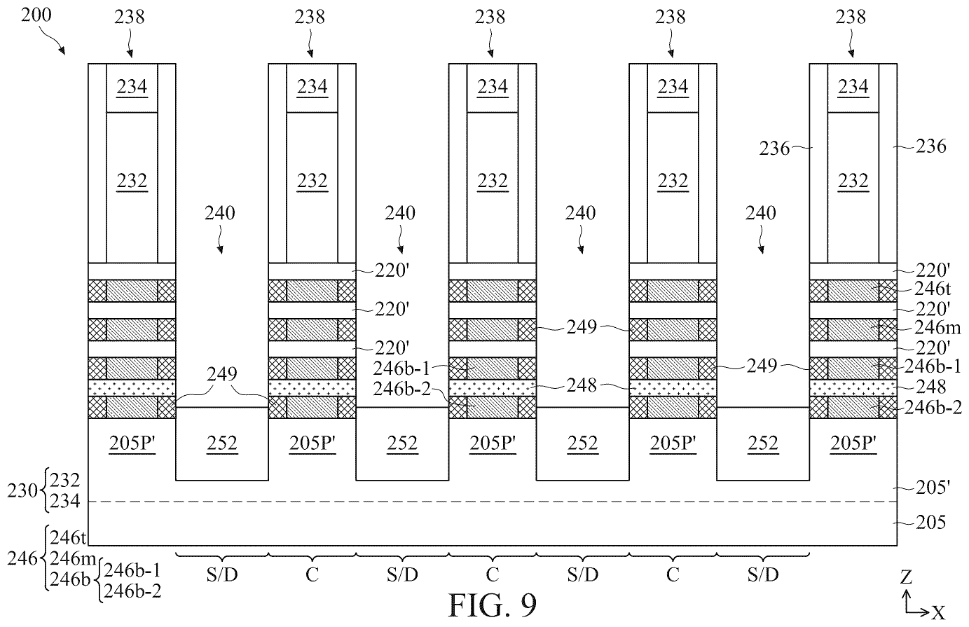

In the depicted embodiment, to facilitate formation of bottom channel isolation structures that may reduce and/or suppress leakage current into underlying substrate 205, a thickness of bottom sacrificial layer (i.e., a sacrificial layer 215b) is configured greater than a thickness of middle sacrificial layers (i.e., a sacrificial layer 215m) and a top sacrificial layer (i.e., a sacrificial layer 215t) of multilayer stack 210. For example, sacrificial layer 215m and sacrificial layer 215t have a thickness t1, sacrificial layer 215b has a thickness t2, and thickness t2 is greater than thickness t1. In some embodiments, a ratio of thickness t2 to thickness t1 is about 2.5 to about 4. If the ratio is greater than about 4, subsequently formed source/drain recesses (e.g., FIG. 3) may have aspect ratios (i.e., ratios of depths to widths) that are too high, which may negatively impact source/drain formation. For example, when forming bottom source/drain insulation (e.g., FIG. 9) in source/drain recesses having high aspect ratios, it may be difficult to remove portions of bottom source/drain insulation that may form along sidewalls of the channel regions and/or tune process parameters to limit source/drain insulation formation to the bottom of the source/drain recesses without damaging other structures of device 200, which may result in yield losses and/or device performance losses. If the ratio is less than about 2.5, thicknesses of sacrificial layers that replace bottom semiconductor layers 215b may be less than thicknesses of sacrificial layers that replace top semiconductor layers 215t and middle semiconductor layers 215m (e.g., FIG. 5)(which are subsequently replaced with gate stacks (e.g., FIG. 13) and inner spacers (e.g., FIG. 8)), which may lead to the gate stacks that include top/middle portions having first thicknesses that are greater than second thicknesses of bottom portions of the gate stacks. The different thicknesses may lead to threshold voltage mismatch and/or non-uniform threshold voltage. Further, ratios less than about 2.5 may provide thinner bottom channel insulation layers (e.g., FIGS. 5-13) and replace bottom semiconductor layers 215b with thinner sacrificial layers (e.g., FIGS. 5-13), which may lead to gate gap fill issues (e.g., if too thin, gaps formed when the sacrificial layers are removed may be too small to adequately fill, which may result in voids in the gate stacks) and/or unintended removal of bottom channel insulation layers (e.g., bottommost sacrificial layers), which may result in higher parasitic capacitance. Semiconductor layers 220 may have a thickness t3 that is greater than, less than, or the same as thickness t1. Thickness t1, thickness t2, and thickness t3 may be chosen based on fabrication and/or device performance considerations. In some embodiments, thickness t3 is configured to provide a desired thickness of channels of transistors, and thickness t1 is configured to provide a desired distance (or spacing) between adjacent channels of transistors (e.g., between semiconductor layers 220). In some embodiments, a thickness of middle sacrificial layers 215m is different than a thickness of top sacrificial layer 215t.

Semiconductor layers 220 or portions thereof may form channels of transistors of device 200. In FIG. 2, multilayer stack 210 includes three sacrificial layers 215 and three semiconductor layers 220. Multilayer stack 210 thus includes three semiconductor layer pairs disposed over substrate 205, each of which have a respective sacrificial layer 215 and a respective semiconductor layer 220. After processing of multilayer stack 210, this configuration may result in transistors having three channels. However, in some embodiments, multilayer stack 210 includes different numbers of semiconductor layers 220 depending, for example, on a number of channels desired for transistors of and/or design requirements of device 200. For example, multilayer stack 210 may include two to ten semiconductor layer pairs, each of which may have a respective sacrificial layer 215 and a respective semiconductor layer 220.

Forming multilayer stack 210 may be include depositing sacrificial layers 215 and semiconductor layers 220 over substrate 205 and patterning sacrificial layers 215, semiconductor layers 220, and substrate 205, such that multilayer stack 210 extends from substrate 205. Sacrificial layers 215 and semiconductor layers 220 are stacked vertically (e.g., along the z-direction) in an interleaving and/or alternating configuration from a top of substrate 205. In some embodiments, the depositing includes epitaxially growing sacrificial layers 215 and semiconductor layers 220 alternatingly, one-after-another, to form a stack of layers over substrate 205. For example, a first one of sacrificial layers 215 is epitaxially grown on substrate 205, a first one of semiconductor layers 220 is epitaxially grown on the first one of sacrificial layers 215, a second one of sacrificial layers 215 is epitaxially grown on the first one of semiconductor layers 220, and so on until multilayer stack 210 has a desired number of sacrificial layers 215 and semiconductor layers 220. In such embodiments, sacrificial layers 215 and semiconductor layers 220 may be referred to as epitaxial layers. In some embodiments, sacrificial layers 215 and semiconductor layers 220 may be epitaxially grown by a molecular beam epitaxy (MBE) process, a chemical vapor deposition (CVD) process, a metalorganic (MOCVD) process, other suitable epitaxial growth process, or combinations thereof.

After patterning, multilayer stack 210 includes mesa 205′ (also referred to as a substrate extension, a substrate fin portion, a fin portion, an etched substrate portion, etc.) and a semiconductor layer stack portion (i.e., semiconductor layer 212, sacrificial layers 215, and semiconductor layers 220). Multilayer stack 210 extends substantially along the x-direction, having a length along the x-direction, a width along a y-direction, and a height along a z-direction. Multilayer stack 210 may extend substantially parallel to other multilayer stacks, which may provide other active regions. In some embodiments, a lithography process and/or an etching process is performed to pattern sacrificial layers 215, semiconductor layers 220, and substrate 205. In some embodiments, multilayer stack 210 is formed by a multiple patterning process, such as a double patterning lithography (DPL) process (e.g., a lithography-etch-lithography-etch (LELE) process, a self-aligned double patterning (SADP) process, a spacer-is-dielectric (SID) process, other double patterning process, or combinations thereof), a triple patterning process (e.g., a lithography-etch-lithography-etch-lithography-etch (LELELE) process, a self-aligned triple patterning (SATP) process, other triple patterning process, or combinations thereof), other multiple patterning process (e.g., self-aligned quadruple patterning (SAQP) process), or combinations thereof. In some embodiments, directed self-assembly (DSA) techniques are implemented while forming multilayer stack 210. In some embodiments, multilayer stack 210 is formed by a fin fabrication process, and multilayer stack 210 can be referred to as a fin, a fin structure, a fin element, an active fin region, an active region, etc.

Substrate isolation structures 225 may be formed adjacent to and around a lower portion of multilayer stack 210 (e.g., mesa 205′ thereof), and multilayer stack 210 may be separated from other multilayer stacks and/or other device regions by substrate isolation structures 225. In some embodiments, substrate isolation structures 225 may be formed by depositing an insulator material (e.g., by a CVD process or a spin-on glass process) over substrate 205 that fills, partially or entirely, the trenches and performing a chemical mechanical polishing (CMP) process to remove excess insulator material and/or planarize top surfaces of substrate isolation structures 225. The deposition process may be a flowable CVD (FCVD) process, a high aspect ratio deposition (HARP) process, a high-density plasma CVD (HDPCVD) process, other suitable deposition process, or combinations thereof. In some embodiments, the CMP process removes insulator material over a top of multilayer stack 210. In some embodiments, the insulator material is etched back, such that multilayer stack 210 extends a distance beyond the top of substrate isolation structures 225 (i.e., a top surface of multilayer stack 210 is higher than top surfaces of substrate isolation structures 225).

Substrate isolation structures 225 may electrically isolate an active device region (e.g., multilayer stack 210) from other device regions, such as another multilayer stack. Substrate isolation structures 225 include silicon oxide, silicon nitride, silicon oxynitride, other suitable isolation material (including, silicon, oxygen, nitrogen, carbon, other suitable isolation constituent, or combinations thereof), or combinations thereof. Substrate isolation structures 225 may have a multilayer structure. For example, substrate isolation structures 225 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 225 may include a bulk dielectric over a doped liner, such as a boron silicate glass (BSG) liner and/or a phosphosilicate glass (PSG) liner. Dimensions and/or characteristics of substrate isolation structures 225 may be configured to provide shallow trench isolation (STI) structures, deep trench isolation (DTI) structures, local oxidation of silicon (LOCOS) structures, other suitable isolation structures, or combinations thereof.

Dummy gate stacks 230 may be formed over channel regions (C) of multilayer stack 210 and between respective source/drain regions (S/D) of multilayer stack 210. Dummy gate stacks 230 extend lengthwise in a direction that is different than (e.g., orthogonal to) the lengthwise direction of multilayer stack 210. For example, dummy gate stacks 230 extend along the y-direction, having a length along the y-direction, a width along the x-direction, and a height along the z-direction. Dummy gate stacks 230 may extend substantially parallel to one another. In FIG. 2 (e.g., the X-Z plane), dummy gate stacks 230 are disposed on top of respective channel regions, and dummy gate stacks 230 are disposed between respective source/drain regions. In a different cross-sectional view (e.g., the Y-Z plane), dummy gate stacks 230 may wrap respective channel regions (e.g., be disposed over the top and sidewalls thereof), and dummy gate stacks 230 may be disposed over tops of substrate isolation structures 225.

Dummy gate stacks 230 include a dummy gate 232 and a hard mask 234. In some embodiments, dummy gates 232 include a dummy gate dielectric and a dummy gate electrode. The dummy gate dielectric includes a dielectric material, such as silicon oxide and/or other suitable dielectric material. The dummy gate electrode includes a suitable dummy gate material, such as polysilicon. In some embodiments, forming dummy gate stacks 230 includes depositing a dummy gate dielectric layer over multilayer stack 210, depositing a dummy gate electrode layer over the dummy gate dielectric layer, and depositing a hard mask layer over the dummy gate electrode layer. One or more lithography and etching processes may then be performed to pattern the hard mask layer, the dummy gate electrode layer, and the dummy gate dielectric layer, and remainders of the hard mask layer, the dummy gate electrode layer, and the dummy gate dielectric layer may form the dummy gate dielectrics, the dummy gate electrodes, and the hard masks, respectively, of dummy gate stacks 230, such as depicted.

Referring to FIG. 2 and FIG. 3, gate spacers 236 are formed along sidewalls of dummy gate stacks 230, thereby forming gate structures 238 (each of which may include a respective dummy gate stack 230 and respective gate spacers 236) and portions of multilayer stack 210 (i.e., source/drain regions of multilayer stack 210, which are not covered by gate structures 238) are at least partially removed to form source/drain recesses (trenches) 240. Gate spacers 236 are disposed adjacent to dummy gate stacks 230. Gate spacers 236 are formed by any suitable process and include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). For example, a spacer layer may be deposited over device 200 and etched to form gate spacers 236. In some embodiments, gate spacers 236 have a multilayer structure, such as a first dielectric layer and a second dielectric layer. In some embodiments, gate spacers 236 include more than one set of spacers, such as seal spacers, offset spacers, sacrificial spacers, dummy spacers, main spacers, or combinations thereof. In such embodiments, the various sets of spacers may have different compositions.

Referring to FIG. 3, a source/drain etch removes semiconductor layers 220 and sacrificial layers 215 in source/drain regions of multilayer stack 210, thereby exposing mesas 205′. The source/drain etch further removes some, but not all, of mesas 205′ in source/drain regions of multilayer stack 210. Source/drain recesses 240 thus extend beyond bottom sacrificial layer 215b (e.g., a distance below a bottom surface of bottom sacrificial layer 215b) in channel regions, and source/drain recesses expose sidewalls of sacrificial layers 215 and semiconductor layers 220 that remain in channel regions of multilayer stack 210. After the source/drain etch, channel regions of multilayer stack 210 may have projecting portions (referred to hereafter as mesas 205P′) formed from mesa 205′ and/or substrate 205. In some embodiments, source/drain recesses 240 extend a distance below tops of substrate isolation structures 225.

The source/drain etch is a dry etch, a wet etch, other suitable etch, or combinations thereof. In some embodiments, the source/drain etch is a multistep etch process, such as a source/drain etch that alternates etchants to remove sacrificial layers 215 and semiconductor layers 220 separately and alternately. In some embodiments, source/drain etch parameters (e.g., etchant thereof) are tuned to selectively remove semiconductor materials (i.e., semiconductor layers 220, sacrificial layers 215, and mesa 205′) with negligible (to no) removal of dielectric materials (e.g., hard masks 234, gate spacers 236, substrate isolation structures 225, etc.).

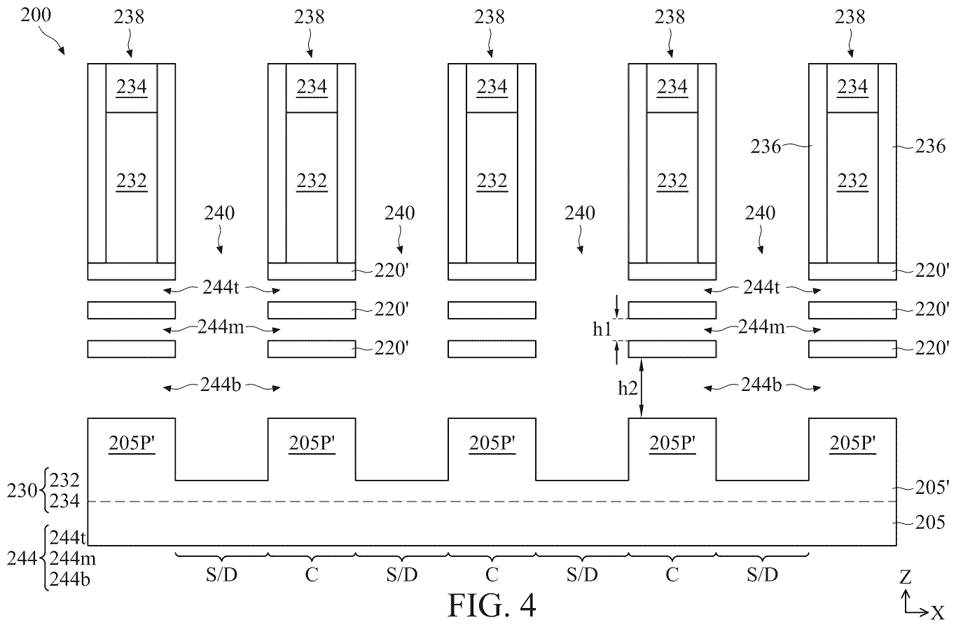

Referring to FIGS. 4-7, remaining sacrificial layers 215 are replaced with sacrificial layers and/or insulation layers depending on thicknesses of sacrificial layers 215. Referring to FIG. 4, an etching process selectively removes sacrificial layers 215 exposed by source/drain recesses 240, thereby forming gaps 244 in channel regions. Because sacrificial layers 215 have different thicknesses, gaps 244 have different heights. For example, gaps 244 include gaps between semiconductor layers 220 having a height h1 (e.g., top gaps 244t and middle gaps 244m) and gaps between bottommost semiconductor layers 220 and mesas 205P′ having a height h2 (e.g., gaps 244b). Height h2 of middle gaps 244b (corresponding with sacrificial layers 215 having thickness t2) is greater than height h1 of top gaps 244t and gaps 244m (corresponding with sacrificial layers 215 having thickness t1). In some embodiments, height h1 is about equal to thickness t1 and/or height h2 is about equal to thickness t2. In some embodiments, height h1 is greater than thickness t1 and/or height h2 is greater than thickness t2.

The etching process may selectively removes sacrificial layers 215 with respect to substrate 205, semiconductor layers 220, dummy gates 230 (e.g., hard masks 234 thereof), gate spacers 236, or combinations thereof. In other words, the etching process removes sacrificial layers 215 with negligible (to no) removal of substrate 205, semiconductor layers 220, dummy gates 230 (e.g., hard masks 234 thereof), gate spacers 236, or combinations thereof. In some embodiments, an etchant is selected for the etching process that etches silicon germanium (e.g., sacrificial layers 215) at a higher rate than silicon (e.g., semiconductor layers 220 and mesa 205′) and dielectric materials (e.g., gate spacers 236 and hard masks 234). The etching process is a dry etch, a wet etch, other suitable etch, or combinations thereof. In some embodiments, before the etching process, an oxidation process may be performed to convert sacrificial layers 215 into semiconductor oxide layers (e.g., silicon germanium oxide layers). In such embodiments, the etching process removes semiconductor oxide layers to form gaps 244.

Semiconductor layers 220 remaining in channel regions are suspended over mesas 205P′ after removing sacrificial layers 215. In the depicted embodiment, each channel region has three suspended semiconductor layers 220, which are referred to hereafter as channel layers 220′. Channel layers 220′ are vertically stacked along the z-direction, and channel layers 220′ may provide three channels through which current can flow between respective, subsequently formed source/drains. In some embodiments, after removing sacrificial layers 215, an etching process may be performed to modify a profile of channel layers 220′ to provide target dimensions and/or target shapes thereof. For example, the etching process may provide channel layers 220′ with cylindrical-shaped profiles (e.g., nanowires), rectangular-shaped profiles (e.g., nanobars), sheet-shaped profiles (e.g., nanosheets (e.g., dimensions in the X-Y plane are sufficiently greater than dimensions in the X-Z plane and the Y-Z plane to form sheet-like structures)), or any other suitable shaped profile. In some embodiments, channel layers 220′ have nanometer-sized dimensions and may be referred to as “nanostructures,” alone or collectively. In some embodiments, channel layers 220′ have sub-nanometer dimensions and/or other suitable dimensions. In some embodiments, the modified profiles of channel layers 220′ may provide height h1 greater than thickness t1 and/or height h2 greater than thickness t2.

Referring to FIG. 5, sacrificial layers 246 are formed in gaps 244. Because gaps 244 have different heights, sacrificial layers 246 fill spaces between channel layers 220′ (e.g., top gaps 244t and middle gaps 244m), but not spaces between bottom channel layers 220′ and mesas 205P′ (e.g., bottom gaps 244b). For example, top sacrificial layers 246t may fill top gaps 244t (having height h1), middle sacrificial layers 246m may fill middle gaps 244m (having height h1), and bottom sacrificial layers 246b may partially fill bottom gaps 244b (having height h2). Top sacrificial layers 246t and middle sacrificial layers 246m have a thickness t4, which may be about equal to height h1. In the depicted embodiment, bottom sacrificial layers 246b include bottom sacrificial layers 246b-1, which fill upper portions of bottom gaps 244b, and bottom sacrificial layers 246b-2, which fill lower portions of bottom gaps 244b. Bottom sacrificial layers 246b-1 are disposed on bottom channel layers 220′ (e.g., bottom surfaces thereof), and bottom sacrificial layers 246b-2 are disposed on mesas 205P′ (e.g., top surfaces thereof). Bottom sacrificial layers 246b-1 have a thickness t5, and bottom sacrificial layers 246b-2 have a thickness t6, which may be the same or different than thickness t5. Thickness t5 and/or thickness t6 may be the same or different than thickness t4. A sum of thickness t5 and thickness t6 is less than height h2, such that remaining bottom gaps 244b have a height h3 that is less than height h2. In the depicted embodiment, middle portions of bottom gaps 244b remain unfilled, such that bottom gaps 244b remain between bottom sacrificial layers 246b-1 and bottom sacrificial layers 246b-2. A sum of thickness t5, thickness t6, and height h3 is about equal to height h2.

A composition of sacrificial layers 246 is different than a composition of channel layers 220′ to achieve etch selectivity. For example, sacrificial layers 246 and channel layers 220′ include different materials, constituent atomic percentages, constituent weight percentages, other characteristics, or combinations thereof. In the depicted embodiment, since some of sacrificial layers 246 (e.g., bottom sacrificial layers 246b-2) will remain in device 200 to improve insulation of channel regions from substrate 205 (e.g., by reducing unwanted leakage current from flowing between doped semiconductor layers 258 through mesas 205P′ and/or substrate), sacrificial layers 246 include a suitable electrically insulating material that also achieves desired etching selectivity. For example, sacrificial layers 246 may include a dielectric material, and channel layers 220′ may include a semiconductor material (e.g., silicon). The dielectric material may include silicon, oxygen, carbon, nitrogen, other suitable dielectric constituent, or combinations thereof. In some embodiments, the dielectric material includes oxygen, and sacrificial layers 246 are oxide layers, such as silicon oxide layers.

In some embodiments, sacrificial layers 246 are formed by depositing a dielectric layer over device 200 and etching the dielectric layer, such that the dielectric layer is removed from source/drain regions, but not channel regions, of device 200. In some embodiments, the as-deposited dielectric layer may fill top gaps 244t and middle gaps 244m, partially fill bottom gaps 244b, partially fill source/drain recesses 240, and line source/drain recesses 240 (e.g., disposed along sidewalls of channel layers 220′, sidewalls of mesas 205P′, and surfaces of mesa 205′ that form bottoms of source/drain recesses 240). The dielectric layer may further be disposed over gate structures 238, such as along tops and sidewalls thereof. In some embodiments, the dielectric layer is formed by a conformal deposition process, and the dielectric layer has a conformal thickness (e.g., substantially uniform, such that thickness t4, thickness t5, and thickness t6 may be the same). In some embodiments, the etching may remove exposed portions of the dielectric layer (e.g., those not filling and/or partially filling gaps 244), such as the portions of the dielectric layer disposed on sidewalls of channel layers 220′, sidewalls of mesas 205P′, surfaces of mesa 205′ that form bottoms of source/drain recesses 240, sidewalls and tops of gate spacers 236, and tops of dummy gate stacks 230 (e.g., hard masks 234 thereof). The dielectric material may be removed by a dry etch, a wet etch, other suitable etch, or combinations thereof. In some embodiments, sacrificial layers 246 (e.g., dielectric layers) are formed by an oxidation process, such as thermal oxidation process. In some embodiments, sacrificial layers 246 are formed by atomic layer deposition (ALD), plasma enhanced chemical vapor deposition (PECVD), other suitable deposition process, or combinations thereof.

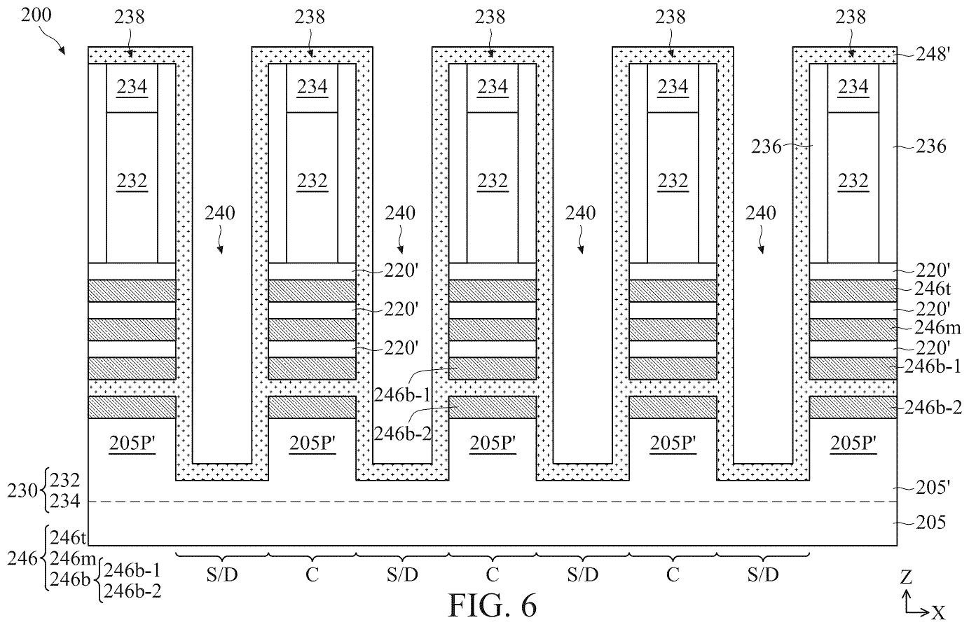

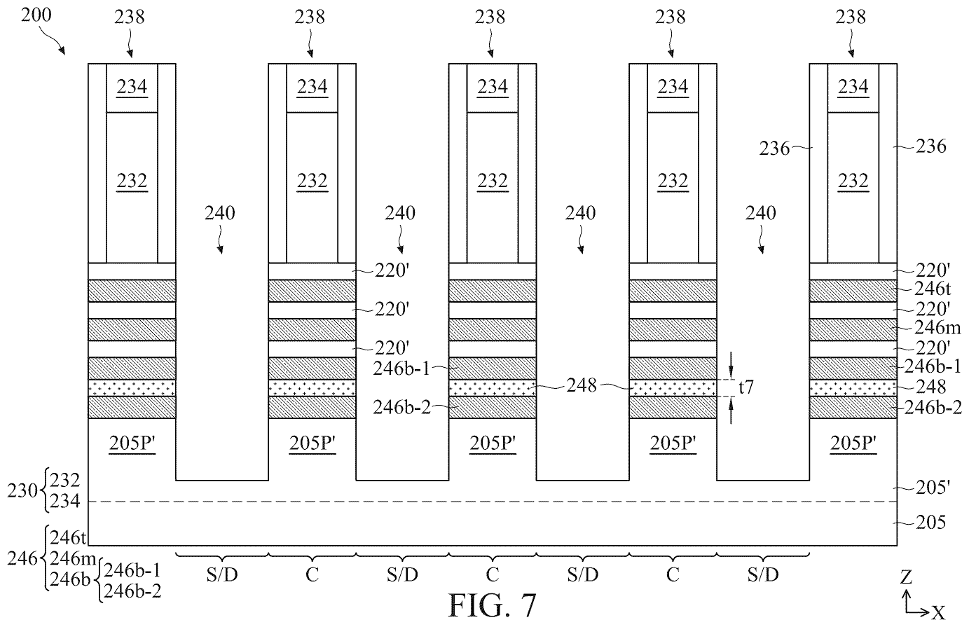

Referring to FIG. 6 and FIG. 7, insulator layers 248 are formed in remainders of gaps 244. In the depicted embodiment, insulator layers 248 fill remainders of bottom gaps 244b, such that insulator layers 248 are disposed between bottom sacrificial layers 246b-1 and bottom sacrificial layers 246b-2. Insulator layers 248 have a thickness t7, which may be about equal to height h3. Thickness t7 may be the same or different than thickness t5 and/or thickness t6. To ensure that additional bottom insulation (i.e., insulator layers 248) may be incorporated into channel regions of device 200, thickness t2 of bottom sacrificial layer 215b (which impacts height h2 of bottom gaps 246b) and/or parameters of the deposition process (e.g., deposition time, deposition precursors, etc.) used to form sacrificial layers 246 are tuned/selected to provide bottom sacrificial layers 246b that do not completely fill bottom gaps 246b. In some embodiments, lengths of insulator layers 248 along the x-direction (e.g., a gate widthwise direction) are substantially the same as lengths of sacrificial layers 246 along the x-direction. Such lengths may also be substantially the same as lengths of channel layers 220′.

Insulator layers 248 include a suitable electrically insulating material, such as a dielectric material. The dielectric material may include silicon, oxygen, carbon, nitrogen, other suitable dielectric constituent, or combinations thereof. A composition of insulator layers 248 is different than a composition of sacrificial layers 246 to achieve etch selectivity. For example, insulator layers 248 and sacrificial layers 246 include different materials, constituent atomic percentages, constituent weight percentages, other characteristics, or combinations thereof. In some embodiments, insulator layers 248 and sacrificial layers 246 include different dielectric materials. In some embodiments, insulator layers 248 are formed of a dielectric material that includes nitrogen, and insulator layers 248 are nitride layers, such as silicon nitride layers. In such embodiments, sacrificial layers 246 may be silicon oxide layers.

Insulator layers 248 may be formed by depositing an insulator material 248′ over device 200 (FIG. 6) and etching insulator material 248′ (FIG. 7). Referring to FIG. 6, insulator material 248′ is disposed on tops of gate structures 238 (e.g., tops of dummy gate stacks 230 (e.g., hard masks 234 thereof) and tops of gate spacers 236), sidewalls of gate structures 238 (e.g., sidewalls of gate spacers 236), sidewalls of semiconductor layers 220, sidewalls of sacrificial layers 246, sidewalls of mesas 205P′, and bottoms of source/drain recesses 240 (e.g., formed by mesa 205′/substrate 205). Insulator material 248′ partially fills source/drain recesses 240, and insulator material 248′ fills remainders of bottom gaps 244b. In the depicted embodiment, insulator material 248′ is formed by a conformal deposition process, and insulator material 248′ has a substantially uniform thickness over vertically oriented surfaces and horizontally oriented surfaces of device 200. For example, a thickness of portions of insulator material 248′ along sidewalls of gate structures 238, sidewalls of semiconductor layers 220, and sidewalls of sacrificial layers 246 may be substantially the same as a thickness of portions of insulator material 248′ along tops of gate structures 238, which may be substantially the same as a thickness of portions of insulator material 248′ along tops of mesa 205′ in source/drain regions. Insulator material 248′ may thus be referred to as a conformal insulator layer. In some embodiments, insulator material 248′ is formed by ALD. In some embodiments, insulator material 248′ is formed by CVD, other suitable process, or combinations thereof.

Referring to FIG. 7, an etching process removes exposed portions of insulator material 248′ (e.g., those not filling gaps 244), such as portions of insulator material 248′ disposed on sidewalls of channel layers 220′, sidewalls of mesas 205P′, sidewalls of sacrificial layers 246, surfaces of mesa 205′ that form bottoms of source/drain recesses 240, sidewalls and tops of gate spacers 236, and tops of dummy gate stacks 230 (e.g., hard masks 234 thereof). Insulator material 248′ remaining in bottom gaps 244b provides insulator layers 248. The etching process is a dry etch, a wet etch, other suitable etch, or combinations thereof. In some embodiments, parameters of the etching process are tuned to remove vertically oriented portions of insulator material 248′, such as that on sidewalls of channel layers 220′, sidewalls of sacrificial layers 246, sidewalls of mesas 205P′, and sidewalls of gate spacers 236. In such embodiments, as a result of etch loading effects, the etching process may also remove horizontally oriented portions of insulator material 248′ on tops of dummy gate stacks 230 (e.g., hard masks 234 thereof) and tops of mesa 215′ in source/drain regions. In some embodiments, a thickness of insulator material 248′ over vertically oriented surfaces may be greater than a thickness of insulator material 248′ over horizontally oriented surfaces.

Referring to FIG. 8, inner spacers 249 may be formed under gate spacers 236 along sidewalls of sacrificial layers 246. Inner spacers 249 may replace edges/ends of sacrificial layers 246, which are disposed under gate spacers 236. In the depicted embodiment, top sacrificial layers 246t and middle sacrificial layers 246m are disposed between respective inner spacers 249 along the x-direction (e.g., the gate widthwise direction), which are disposed between edges/ends of channel layers 220′ along the z-direction (e.g., the gate height direction); bottom sacrificial layers 246b-1 are disposed between respective inner spacers 249 along the x-direction, which are disposed between edges/ends of bottom channel layers 220′ and edges/ends of insulator layers 248 along the z-direction; and bottom sacrificial layers 246b-2 are disposed between respective inner spacers 249 along the x-direction, which are disposed between edges/ends of insulator layers 248 and edges/ends of mesas 205P′ along the z-direction.

Forming inner spacers 249 may include a first etching process, a deposition process, and a second etching process. The first etching process may selectively etch sacrificial layers 246 with negligible (to no) etching of insulator layers 248, channel layers 220′, mesas 205P′, dummy gate stacks 230 (e.g., hard masks 234 thereof), gate spacers 236, substrate isolation structures 225, or combinations thereof. The first etching process may be configured to laterally etch (e.g., along the x-direction and/or the y-direction) sacrificial layers 246 to reduce lengths thereof along the x-direction, such that lengths of sacrificial layers 246 are less than lengths of insulator layers 248 after forming inner spacers 249. The first etching process may form inner spacer recesses between channel layers 220′, between insulator layers 248 and bottom channel layers 220′, and between insulator layers 248 and mesas 205P′. In some embodiments, the inner spacer recesses laterally extend (e.g., along the x-direction) under dummy gate stacks 230. Because sacrificial layers 246 and insulator layers 248 have different compositions (e.g., different dielectric materials), the first etching process does not remove (or negligibly removes) insulator layers 248, such that a length of insulator layers 248 may remain the same as a length of channel layers 220′. The first etching process is a dry etch, a wet etch, other suitable etch, or combinations thereof. In some embodiments, the first etching process is an anisotropic etch.

The deposition process may form an inner spacer layer over device 200 that may fill the inner spacer recesses. In some embodiments, a single deposition process is performed to form an inner spacer layer that fills the inner spacer recesses. In some embodiments, more than one deposition process is performed to form the inner spacer layer, such as a first deposition process to form a first inner spacer sublayer and a second deposition process to form a second inner spacer sublayer. The first inner spacer sublayer may partially fill the inner spacer recesses, and the second inner spacer sublayer may partially or completely fill the inner spacer recesses. A composition and/or a material of the first inner spacer sublayer may be the same or different than a composition and/or a material of the second inner spacer sublayer. In embodiments where the first inner spacer sublayer and the second inner spacer sublayer have different compositions and/or materials, inner spacers 249 have multilayer structures (e.g., first and second inner spacer sublayers). In some embodiments, inner spacers 249 include air gaps (voids).

The second etching process may selectively etch the inner spacer layer with negligible (to no) etching of insulator layers 248, channel layers 220′, mesas 205P′, dummy gate stacks 230 (e.g., hard masks 234 thereof), gate spacers 236, substrate isolation structures 225, or combinations thereof. Remainders of the inner spacer layer provide inner spacers 249, such as depicted. To achieve desired etching selectivity during the second etching process, the inner spacer layer (and thus inner spacers 249) has a composition different than compositions of insulator layers 248, channel layers 220′, mesas 205P′, dummy gate stacks 230 (e.g., hard masks 234 thereof), gate spacers 236, substrate isolation structures 225, or combinations thereof. In some embodiments, the inner spacer layer includes a dielectric material that includes silicon, oxygen, carbon, nitrogen, other suitable dielectric constituent, or combinations thereof. For example, the inner spacer layer is a silicon carbide layer, a silicon carbonitride layer, a silicon oxycarbonitride layer, a silicon oxycarbide layer, or combinations thereof. The second etching process is a dry etch, a wet etch, other suitable etch, or combinations thereof.

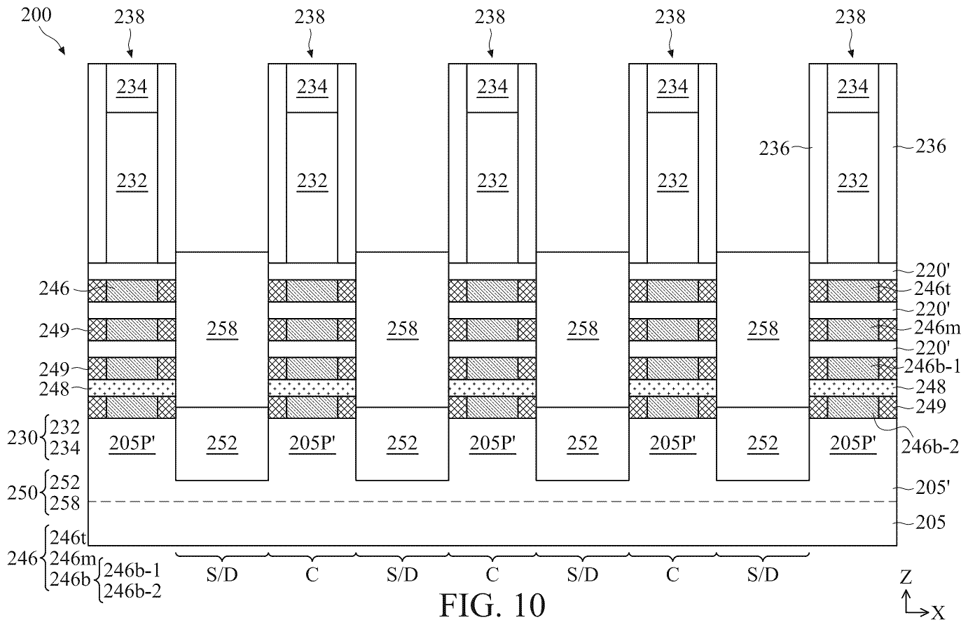

Referring to FIG. 9 and FIG. 10, source/drain structures 250 are formed in source/drain recesses 240. Source/drain structures 250 may include insulator layers 252 and doped semiconductor layers 258. Referring to FIG. 9, insulator layers 252 are formed in bottoms of source/drain recesses 240, insulator layers 252 partially fill source/drain recesses 240, and insulator layers 252 are disposed on mesas 205P′ and/or mesa 205′. In some embodiments, such as depicted, insulator layers 252 fill bottom portions of source/drain recesses 240 formed by substrate 205, and insulator layers 252 extend a distance above top surfaces of mesas 205P′. In such embodiments, top surfaces of insulator layers 252 are above top surfaces of mesas 205P′, and a thickness of insulator layers 252 may be greater than a height of mesas 205P′. In furtherance of the depicted embodiment, a distance between top surfaces of insulator layers 252 and top surfaces of mesas 205P′ is less than a thickness of bottom sacrificial layers 246b-2 (i.e., thickness t6), such that insulator layers 252 are disposed below insulator layers 248. Bottommost inner spacers 249 are thus disposed between insulator layers 252 and bottom sacrificial layers 246b-2. In some embodiments, insulator layers 252 may extend to insulator layers 248 (e.g., to bottom surfaces thereof). In some embodiments, insulator layers 252 may extend above tops of bottom sacrificial layers 246b-2 and along sidewalls of insulator layers 248. In some embodiments, insulator layers 252 may extend to but not beyond bottom sacrificial layers 246b-1 (e.g., to bottom surfaces thereof). In some embodiments, a thickness of insulator layers 252 is substantially the same as a height of mesas 205P′. In some embodiments, a thickness of insulator layers 252 is greater than a height of mesas 205P′.

Insulator layers 252 include an electrically insulating material, such as a dielectric material, that may reduce unwanted leakage current from flowing between doped semiconductor layers 258 through mesas 205P′ and/or substrate 205. In some embodiments, insulator layers 252 include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. In some embodiments, insulator layers 252 include a metal-comprising dielectric material, such as a metal oxide material (e.g., aluminum oxide and/or hafnium oxide) and/or a metal nitride material. In some embodiments, insulator layers 252 include a doped semiconductor material that includes an opposite type of dopant than doped semiconductor layers 258 of source/drain structures 250. For example, where source/drain structures 250 are portions of p-type transistors having p-type doped semiconductor layers, insulator layers 252 may include an n-type doped semiconductor material, such as phosphorous-doped silicon. In another example, where source/drain structures 250 are portions of n-type transistors having n-type doped semiconductor layers, insulator layers 252 may include p-doped semiconductor material, such as boron-doped silicon.

Insulator layers 252 may be formed by depositing an insulator material over device 200 and etching the insulator material, such that remainders of the insulator material fill bottoms of source/drain recesses 240. The as-deposited insulator material may be disposed on tops of gate structures 238 (e.g., tops of gate spacers 236 and tops of dummy gate stacks 230 (e.g., hard masks 234 thereof)), sidewalls of gate structures 238 (e.g., sidewalls of gate spacers 236), sidewalls of channel layers 220′, sidewalls of insulator layers 248, sidewalls of inner spacers 249, sidewalls of mesas 205P′, and tops of mesa 205′ in source/drain regions. In some embodiments, as a result of properties of a deposition process (e.g., physical vapor deposition (PVD)), a thickness of the insulator material over horizontally oriented surfaces (e.g., tops of mesa 205′ in source/drain regions and tops of gate structures 238) may be greater than a thickness of vertically oriented surfaces (e.g., sidewalls of gate structures 238, sidewalls of channel layers 220′, sidewalls of insulator layers 248, and sidewalls of inner spacers 249). In such embodiments, parameters of the etching may be tuned to remove vertically oriented portions of the insulator material, such as that on sidewalls of gate structures 238, sidewalls of channel layers 220′, sidewalls of insulator layers 248, and sidewalls of inner spacers 249. In such embodiments, as a result of etch loading effects, the etching may also remove horizontally oriented portions of the insulator material on tops of gate structures 238, but not (or minimally) horizontally oriented portions and/or vertically oriented portions of the insulator material in bottoms of source/drain recesses 240, such as that disposed on mesas 205P′ and/or mesa 205′ (i.e., the etching process may thin but not substantially remove such portions). In some embodiments, the as-deposited insulator material fills source/drain recesses 240 and the etching recesses the insulator material at least to bottom sacrificial layers 246b and/or insulator layers 248. The etching may be a dry etch, a wet etch, other suitable etch, or combinations thereof.

Referring to FIG. 10, doped semiconductor layers 258 are formed in source/drain recesses 240 over insulator layers 252. Doped semiconductor layers 258 fill remainders of source/drain recesses 240, and doped semiconductor layers 258 are coupled to channel layers 220′. Doped semiconductor layers 258 include a semiconductor material (e.g., silicon, germanium, silicon germanium, other suitable semiconductor materials, or combinations thereof) that is doped with n-type dopants and/or p-type dopants. For example, doped semiconductor layers 258 may include silicon doped with carbon, phosphorous, arsenic, antimony, other n-type dopant, or combinations thereof. In such embodiments, doped semiconductor layers 258 may form source/drains of n-type transistors. In another example, doped semiconductor layers 258 may include silicon germanium (and/or germanium) doped with boron, gallium, other p-type dopant, or combinations thereof. In such embodiments, doped semiconductor layers 258 may provide source/drains of p-type transistors. In some embodiments, doped semiconductor layers 258 include multiple layers. For example, doped semiconductor layers 258 may include a heavily doped semiconductor layer over a lightly doped semiconductor layer(s). The lightly doped semiconductor layer(s) may be between the heavily doped semiconductor layer and channel layers 220′. A dopant concentration of the heavily doped semiconductor layer is greater than a dopant concentration of the lightly doped semiconductor layer. In some embodiments, doped semiconductor layers 258 include materials and/or dopants that provide desired tensile stress and/or compressive stress in channel regions (e.g., channel layers 220′).

Doped semiconductor layers 258 may be deposited on and/or grown from channel layers 220′. In some embodiments, doped semiconductor layers 258 are formed by a selective epitaxial growth (SEG) process that selectively deposits (grows) semiconductor material (e.g., silicon or silicon germanium) from exposed semiconductor surfaces, such as sidewalls of channel layers 220′. In such embodiments, doped semiconductor layers 258 may be referred to as doped epitaxial layers. The SEG process may use CVD deposition techniques (e.g., vapor-phase epitaxy (VPE), ultra-high vacuum CVD (UHV-CVD), LPCVD, PECVD, or the like), molecular beam epitaxy, other suitable process, or combinations thereof. In some embodiments, doped semiconductor layers 258 are doped during deposition (i.e., in-situ doped), for example, by adding dopant to a source material of the SEG process. In some embodiments, doped semiconductor layers 258 are doped after deposition, such as by an ion implantation process performed after depositing semiconductor material into source/drain recesses 240. In some embodiments, annealing is performed to activate dopants in doped semiconductor layers 258 and/or other source/drain regions, such as source/drain junction implant regions.

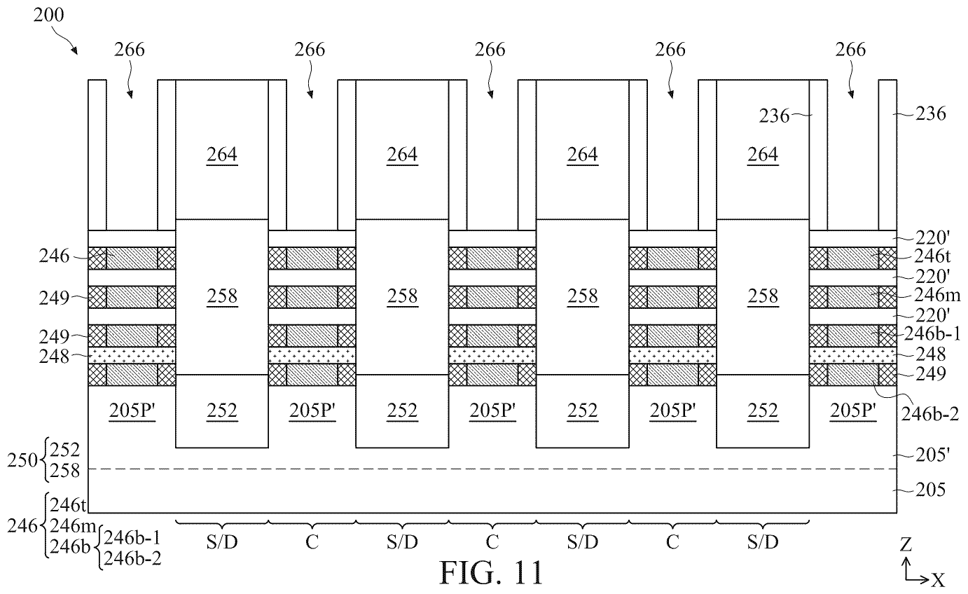

Referring to FIG. 11, a dielectric layer 264 may be formed over device 200, such as over source/drain structures 250 and substrate isolation structures 225. Dielectric layer 264 may fill spaces between adjacent gate structures 238, such as spaces between gate spacers 236 thereof, and spaces between adjacent source/drain structures 250. Forming dielectric layer 264 may include depositing a contact etch stop layer (CESL), depositing an interlayer dielectric (ILD) layer over the CESL, and performing a CMP and/or other planarization process until reaching dummy gate stacks 230. The planarization process may partially remove dummy gate stacks 230, such as hard masks 234 thereof, to expose underlying dummy (e.g., poly) gates 232. The planarization process may reduce heights of dummy gate stacks 230 and/or gate spacers 236. The CESL and the ILD layer are formed by CVD and/or the like. In some embodiments, the ILD layer is formed by FCVD, HARP, HDPCVD, or combinations thereof.

The ILD layer includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass, fluorosilicate glass, xerogel, aerogel, amorphous fluorinated carbon, parylene, benzocyclobutene-based (BCB) dielectric material, polyimide, other suitable dielectric material, or combinations thereof. In some embodiments, the ILD layer includes a low-k dielectric material having a dielectric constant that is less than a dielectric constant of silicon dioxide (e.g., k<3.9). In some embodiments, the ILD layer includes a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or combinations thereof, each of which is tuned/configured to exhibit a dielectric constant less than about 2.5. The CESL includes a material different than the ILD layer, such as a dielectric material that is different than the dielectric material of the ILD layer. For example, where the ILD layer includes a silicon-and-oxygen comprising low-k dielectric material, the CESL may include silicon and nitrogen, such as silicon nitride or silicon oxynitride. The ILD layer and/or the CESL may have a multilayer structure and/or include multiple dielectric materials.

Referring to FIGS. 11-13, a gate replacement process is performed to replace dummy gate stacks 230 (e.g., dummy gates 232 thereof) with gates that at least partially surround channel layers 220′. Referring to FIG. 11, gate openings 266 are formed in gate structures 238 by removing dummy gates 232. For example, an etching process selectively removes dummy gates 232 with respect to dielectric layer 264, insulator layers 248, inner spacers 249, sacrificial layers 246, gate spacers 236, channel layers 220′, substrate isolation structures 225, or combinations thereof. In other words, the etching process removes dummy gates 232 with negligible (to no) removal of dielectric layer 264, insulator layers 248, inner spacers 249, sacrificial layers 246, gate spacers 236, channel layers 220′, substrate isolation structures 225, or combinations thereof. For example, an etchant is selected for the etching process that removes polysilicon (i.e., dummy gates 232) at a higher rate than dielectric materials (e.g., dielectric layer 264, insulator layers 248, inner spacers 249, sacrificial layers 246, gate spacers 236, substrate isolation structures 225, etc.) and semiconductor materials (e.g., channel layers 220′). The etching process is a dry etch, a wet etch, other suitable etch, or combinations thereof. In some embodiments, the etch process includes multiple steps. In some embodiments, a patterned mask layer covers dielectric layer 264 and/or gate spacers 236, and the patterned mask layer has openings therein that expose dummy gate stacks 230 (e.g., dummy gates 232 thereof).

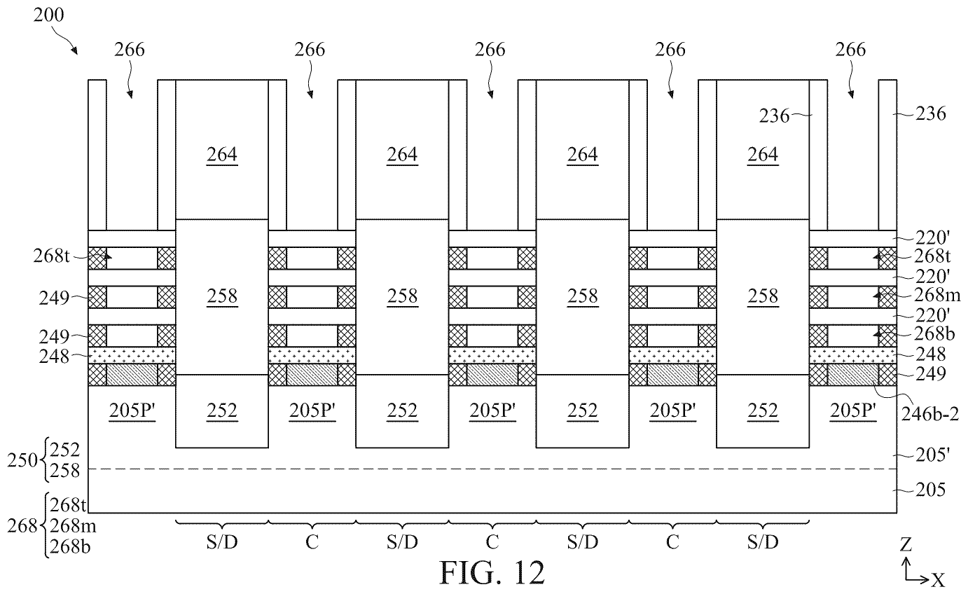

Referring to FIG. 12, sacrificial layers 246 above insulator layers 248 are removed from channel regions, thereby forming gaps (openings) 268 that expose channel layers 220′. Gate openings 266 are thus extended between channel layers 220′ and between channel layers 220′ and insulator layers 248. In the depicted embodiment, top gaps 268t and middle gaps 268m are between respective channel layers 220′ after removing top sacrificial layers 264t and middle sacrificial layers 264m, respectively, and bottom gaps 268b are between respective channel layers 220′ and respective insulator layers 248 after removing bottom sacrificial layers 246b-1. In furtherance of the depicted embodiment, bottom sacrificial layers 246b-2, which are below and protected by insulator layers 248, are not removed from channel regions. Bottom sacrificial layers 246b-2 thus remain between insulator layers 248 and mesas 205P′. In some embodiments, bottom sacrificial layers 246b-1 are positioned above top surfaces of substrate isolation structures 225, while bottoms sacrificial layers 246b-2 are positioned below top surfaces of substrate isolation structures 225. In such embodiments, sacrificial layers 246 above tops surfaces of substrate isolation structures 225 are removed to extend gate openings 266, and sacrificial layers 246 below top surfaces of substrate isolation structures 225 remain.

In some embodiments, an etching process selectively removes sacrificial layers 246 with respect to channel layers 220′, insulator layers 248, inner spacers 249, gate spacers 236, dielectric layer 264, or combinations thereof. In other words, the etching process removes sacrificial layers 246 with negligible (to no) removal of channel layers 220′, insulator layers 248, inner spacers 249, gate spacers 236, dielectric layer 264, or combinations thereof. For example, an etchant is selected for the etching process that etches a dielectric material having a first composition (e.g., sacrificial layers 246) at a higher rate than silicon (e.g., channel layers 220′) and dielectric materials having compositions different than the first composition (e.g., insulator layers 248, inner spacers 249, gate spacers 236, dielectric layer 264, etc.) (i.e., the etchant has a high etch selectivity with respect to the dielectric material having the first composition). The etching process is a dry etch, a wet etch, other suitable etch, or combinations thereof. In some embodiments, the etchant is a fluorine-based etchant, such as hydrofluoric acid (HF) or a mixture of HF and ammonium fluoride (NH₄F). In some embodiments, fluorine-based etchant is a wet etchant. In some embodiments, before the etching process, a patterned mask layer is formed over device 200 that covers dielectric layer 264 and/or gate spacers 236. The patterned mask layer may have openings therein that correspond with gate openings 266, and the etching process may use the patterned mask layer as an etch mask, such sacrificial layers 246 may be selectively removed relative to channel layers 220′, insulator layers 248, inner spacers 249, and gate spacers 236. In some embodiments, a patterned mask layer used during removal of dummy gates 232 to form gate openings 266 may be used during removal of sacrificial layers 246.

Referring to FIG. 13 and FIG. 14, gate stacks 270 (also referred to as high-k/metal gates) may then be formed in gate openings 266 and gaps 268. In FIG. 13 (e.g., a cross-sectional view along a gate widthwise direction), gate stacks 270 include top gate portions 270t disposed over topmost channel layers 220′, middle gate portions 270m disposed between respective channel layers 220′, and bottom gate portions 270b disposed between bottommost channel layers 220′ and insulator layers 248. Further, top gate portions 270t are disposed between respective gate spacers 236, middle gate portions 270m are disposed between respective inner spacers 249, and bottom gate portions 270b are disposed between respective inner spacers 249. Because bottom sacrificial layers 246b-2 remain in channel regions, bottom gate portions 270b (and channel layers 220′ thereover) are separated from mesas 205P′ and/or substrate 205 by both insulator layers 248 and bottom sacrificial layers 246b-2. Device 200 is thus configured with bottom channel insulation structures 280, each of which may include a respective insulator layer 248 and a respective sacrificial layer 246b-2 disposed between respective inner spacers 249. Sacrificial layer 246b-2 is thus referred to as insulator layer 246b-2 hereafter.

In FIG. 14 (e.g., a cross-sectional view along a gate lengthwise direction), gate stacks 270 surround respective channel layers 220′, and gate stacks 270 may be disposed on insulator layers 248 and/or insulator layers 246b-2 depending on heights of substrate isolation structures 225. In the depicted embodiment, heights of substrate isolation structures 225 are greater than a sum of a height of mesas 205P′ and a thickness of sacrificial layers 246b-2 (e.g., thickness t6), but less than a sum of the height of mesas 205P′, the thickness of insulator layers 246b-2 (e.g., thickness t6), and a thickness of insulator layers 248 (e.g., thickness t7). Accordingly, gate stacks 270 are disposed on tops and upper portions of sidewalls of insulator layers 248, such that gate stacks 270 may wrap insulator layers 248, and substrate isolation structures 225 are disposed on lower portions of sidewalls of insulator layers 248. Further, insulator layers 246b-2 are disposed below top surfaces of substrate isolation structures 225, and substrate isolation structures 225 are disposed on sidewalls of insulator layers 246b-2. In some embodiments, gate stacks 270 may cover an entirety of sidewalls of insulator layers 248, such as where substrate isolation structures 225 do not extend beyond top surfaces of insulator layers 246b-2. In some embodiments, gate stacks 270 may be disposed on sidewalls of insulator layers 246b-2, such as where substrate isolation structures 225 do not extend to top surfaces of insulator layers 246b-2. In some embodiments, gate stacks 270 may wrap and/or partially surround respective channel layers 220′ (i.e., be disposed on at least two sides thereof).

Gate stacks 270 may include a respective gate dielectric 272. Gate dielectrics 272 are disposed on respective channel layers 220′, insulator layers 248, inner spacers 249, gate spacers 236, substrate isolation structures 225, or combinations thereof. Because bottom channel insulation structures 280 are on mesas 205P′, gate dielectrics 272 do not directly contact mesas 205P′. Compositions and/or configurations of gate dielectrics 272 may be the same or different. In some embodiments, gate dielectrics 272 include at least one dielectric gate layer, such as an interfacial layer and/or a high-k dielectric layer. The interfacial layer includes a dielectric material, such as SiO₂, SiGeOₓ, HfSiO, SiON, other dielectric material, or combinations thereof. The high-k dielectric layer includes a high-k dielectric material, which generally refers to dielectric materials having a dielectric constant greater than a dielectric constant of silicon dioxide, such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), HfO₂—Al₂O₃, other high-k dielectric material, or combinations thereof. In some embodiments, gate dielectrics 272 include a hafnium-based oxide (e.g., HfO₂) layer and/or a zirconium-based oxide (e.g., ZrO₂) layer.

Gate stacks 270 may include a respective gate electrode 274 disposed over its respective gate dielectric 272. Compositions and/or configurations of gate electrodes 274 may be the same or different. In some embodiments, gate electrodes 274 include an electrically conductive gate layer formed of an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, the electrically conductive gate layer includes a work function layer, which may be tuned to have a desired work function (e.g., an n-type work function or a p-type work function). The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, the electrically conductive gate layer includes a bulk layer over the gate dielectric and/or the work function layer. The bulk layer may include Al, W, Cu, Ti, Ta, TiN, TaN, polysilicon, other suitable metal(s) and/or alloys thereof, or combinations thereof. In some embodiments, the electrically conductive gate layer includes a barrier layer over the work function layer and/or the gate dielectric. The barrier layer includes a material that may prevent diffusion and/or reaction of constituents between adjacent layers and/or promote adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Forming gate stacks 270 may include depositing gate dielectric material (e.g., interfacial layers, high-k dielectric layers, etc.) that partially fill the gate openings, depositing gate electrode material (e.g., work function layers, barrier layers, bulk layers, etc.) that fill remainders of the gate openings, and performing a planarization process to remove portions of the gate dielectric material and/or portions of the gate electrode material over dielectric layer 264. In some embodiments, fabrication of device 200 may further include etching back gate stacks 270 and forming hard masks (e.g., self-aligned cap (SAC) structures) over the etched-back gate stacks 270. The hard masks include a material that is different than dielectric layer 264 and/or subsequently formed dielectric layers to achieve etch selectivity. In some embodiments, the hard masks include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, the hard masks include metal and oxygen and/or nitrogen, such as aluminum oxide, aluminum nitride, aluminum oxynitride, zirconium oxide, zirconium nitride, hafnium oxide, zirconium aluminum oxide, other metal oxide, other metal nitride, or combinations thereof.

Gate stacks 270 are configured to achieve desired functionality according to design requirements of device 200, and gate stacks 270 may have different layers in different device regions depending on configurations thereof. For example, a number, configuration, materials, or combinations thereof of layers of gate dielectrics 272 and/or gate electrodes 274 corresponding with a p-type transistor region may be different than a number, configuration, materials, or combinations thereof of layers of gate dielectrics 272 and/or gate electrodes 274 corresponding with an n-type transistor region. In another example, a number, configuration, materials, or combinations thereof of layers of gate dielectrics 272 and/or gate electrodes 274 corresponding with a first n-type transistor region may be different than a number, configuration, materials, or combinations thereof of layers of gate dielectrics 272 and/or gate electrodes 274 corresponding with a second n-type transistor region. In yet another example, a number, configuration, materials, or combinations thereof of layers of gate dielectrics 272 and/or gate electrodes 274 corresponding with a first p-type transistor region may be different than a number, configuration, materials, or combinations thereof of layers of gate dielectrics 272 and/or gate electrodes 274 corresponding with a second p-type transistor region. Gate stacks 270 may include numerous other layers, for example, capping layers, interface layers, diffusion layers, barrier layers, hard mask layers, or combinations thereof.

Device 200 may thus include various transistors T. Each transistor T may include respective channels (e.g., channel layers 220′), source/drains (e.g., source/drain structures 250), and a respective gate (e.g., gate stack 270). Each gate (e.g., gate stack 270) is disposed between respective source/drains (e.g., source/drain structures 250) along the x-direction, and inner spacers 249 are disposed between each gate and its respective source/drains. Further, each gate (e.g., gate stack 270) engages respective channels (e.g., channel layers 220′), and the respective channels extend between the respective source/drains (e.g., source/drain structures 250) along the x-direction. Each gate may surround its respective channel layers, and along the gate lengthwise direction, each gate may include a gate dielectric (e.g., gate dielectric 272) and a gate electrode (e.g., gate electrode 274) that surrounds its respective channels. Further, in the depicted embodiment, each transistor T may include bottom channel insulation (e.g., a respective bottom channel insulation structure 280) and bottom source/drain insulation (e.g., insulator layers 252). Providing transistors T with the bottom source/drain insulation and the multilayer bottom channel insulation (e.g., a respective insulator layer 248 and a respective insulator layer 246b-2) further separates and/or isolates their respective source/drains and their respective gates from an underlying substrate (e.g., substrate 205, mesa 205′, mesas 205P′, or combinations thereof), which may reduce and/or eliminate leakage current into the underlying substrate, such as that which may flow from the source/drains into the underlying substrate. Reducing and/or eliminating the unwanted leakage current improves overall transistor performance.

In some embodiments, bottom source/drain insulation of device 200 may include insulator layers 252 and undoped semiconductor layers, such as depicted in FIG. 15. In such embodiments, source/drain structures 250 may include undoped semiconductor layers 290, insulator layers 252, and doped semiconductor layers 258. Referring to FIG. 15, undoped semiconductor layers 290 may be formed in bottoms of source/drain recesses 240 before insulator layers 292. Undoped semiconductor layers 290 are thus disposed on mesas 205P′ and/or mesa 205′, and undoped semiconductor layers 290 partially fill portions of source/drain recesses 240 formed by substrate 205, such that top surfaces of undoped semiconductor layers 290 are below top surfaces of mesas 205P′. In such embodiments, a thickness of undoped semiconductor layers 290 is less than a height of mesas 205P′, and insulator layers 248 fill remainders of the portions of source/drain recesses 240 formed by substrate 205. In some embodiments, a thickness of undoped semiconductor layers 290 may fill the portions of source/drain recesses 240 formed by substrate 205. In such embodiments, a thickness of undoped semiconductor layers 290 is about equal to the height of mesas 205P′, and insulator layers 252 may not be disposed below top surfaces of mesas 205P′.

Undoped semiconductor layers 290 are dopant-free (i.e., substantially free of n-type dopants and p-type dopants). For example, no intentional doping is performed when forming undoped epitaxial layers (e.g., by an epitaxial growth process). Undoped semiconductor layers 290 may provide high resistance paths at bottoms of source/drain recesses 240, thereby suppressing leakage current into substrate 205. In some embodiments, undoped semiconductor layers 290 include silicon, germanium, silicon germanium, other suitable semiconductor materials, or combinations thereof. For example, undoped semiconductor layers 290 may include dopant-free silicon or dopant-free silicon germanium. In some embodiments, undoped semiconductor layers 290 may be deposited on and/or grown from substrate 205, mesa 205′, mesas 205P′, or combinations thereof. In some embodiments, undoped semiconductor layers 290 are formed by an SEG process that selectively deposits (grows) semiconductor material (e.g., silicon or silicon germanium) from exposed semiconductor surfaces. In such embodiments, undoped semiconductor layers 290 may be referred to as undoped epitaxial layers. The SEG process may use CVD deposition techniques (e.g., VPE, UHV-CVD, LPCVD, PECVD, or the like), molecular beam epitaxy, other suitable process, or combinations thereof. In some embodiments, undoped semiconductor layers 290 are formed by a bottom-up deposition process (which may be an SEG process), such that semiconductor material is deposited on mesas 205P′, mesa 205′, and/or substrate 205 (i.e., in bottom of source/drain recesses 240) with minimal (to no) deposition of semiconductor material on channel layers 220′. In some embodiments, an etching process is performed after the bottom-up deposition process to remove any semiconductor material that may have formed on channel layers 220′. The post-deposition etch may be a dry etch, a wet etch, other suitable etch, or combinations thereof.

The present disclosure contemplates various configurations of bottom channel insulation structure 280. The configuration of bottom channel insulation structure may depend on a thickness of bottom sacrificial layer 215 (e.g., thickness t2), a height of mesas 205P′, a height of substrate isolation structures 225, a depth of source/drain recesses 240, a thickness of bottom source/drain isolation (e.g., a thickness of insulator layers 252), other factors, or combinations thereof. The various factors may be tuned/selected to achieve desired configurations of bottom channel insulation structures 280 relative to source/drain structures 250, such as relative to source/drains and/or bottom source/drain insulation structures thereof. In FIG. 13 and FIG. 14, bottom channel insulation structures 280 are provided above and below bottoms of source/drains (e.g., doped semiconductor layers 258), and bottom channel insulation structures 280 are adjacent to the source/drains and bottom source/drain insulation structures (e.g., insulator layers 252) of source/drain structures 250. For example, insulator layers 248 are disposed above bottoms of doped semiconductor layers 258, and insulator layers 246b-2 and bottommost inner spacers 249 are disposed above and below bottoms of doped semiconductor layers 258. In such example, insulation layers 248 may be disposed above top surfaces of insulation layers 252, insulation layers 246b-2 and bottommost inner spacers 249 may have upper portions disposed above top surfaces of insulation layers 252, and insulation layers 246b-2 and bottommost inner spacers 249 may have lower portions disposed below top surfaces of insulation layers 252. The lower portions may also be disposed above bottom surfaces of insulation layers 252. Insulation layers 252 may thus directly contact and extend along lower sidewall portions of bottommost inner spacers 249, and doped semiconductor layers 258 may directly contact and/or extend along sidewalls of insulation layers 248 and/or upper sidewall portions of bottommost inner spacers 249. In such embodiments, bottoms of bottom source/drain insultation structures are lower than bottoms of bottom channel insulation structures 280 (e.g., FIG. 13 and FIG. 15).

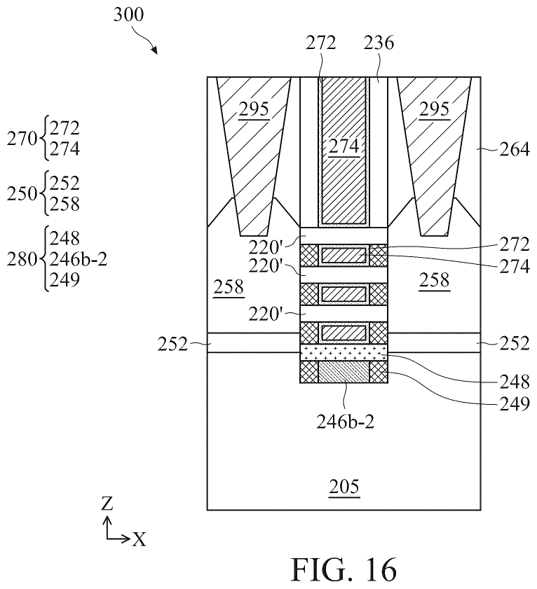

In some embodiments, referring to FIG. 16, bottom channel insulation structures 280 may be provided below bottoms of source/drains (e.g., doped semiconductor layers 258), and bottom channel insulation structures 280 may be adjacent to bottom source/drain insulation structures (e.g., insulator layers 252), but not the source/drains, of source/drain structures 250. FIG. 16 is a cross-sectional view of a device 300, in portion or entirety, according to various aspects of the present disclosure. Device 300 is similar in many respects to device 200. Similar features of device 300 and device 200 are thus identified by the same reference numerals for simplicity and clarity. In FIG. 16, insulator layers 248, insulator layers 246b-2, and bottommost inner spacers 249 are disposed below bottoms of doped semiconductor layers 258. In some embodiments, bottom channel insulation structures 280 are disposed below top surfaces of bottom source/drain channel insulation structures (e.g., formed by top surfaces of insulation layers 254). For example, insulation layers 248 may have upper portions disposed above bottom surfaces of insulation layers 252, insulation layers 248 may have lower portions disposed below bottoms surfaces of insulation layers 252, and insulation layers 246b-2 and bottommost inner spacers 249 may be disposed below bottom surfaces of insulation layers 252. Insulation layers 252 may thus directly contact and extend along upper sidewall portions of insulation layers 248, and substrate 205 and/or mesa 205′ may directly contact and/or extend along sidewalls of bottommost inner spacers 249 and/or lower sidewall portions of insulation layers 248. In such embodiments, bottoms of bottom source/drain insultation structures are higher than bottoms of bottom channel insulation structures 280. In some embodiments, undoped semiconductor layers 290 may directly contact and/or extend along sidewalls of bottommost inner spacers 249 and/or lower sidewall portions of insulation layers 248. In some embodiments, device 300 and/or device 200 includes source/drain contacts 295 disposed in dielectric layer 264 and on doped semiconductor layers 258, such as in the depicted embodiment. FIG. 16 has been simplified for the sake of clarity to better understand the inventive concepts of the present disclosure. Additional features may be added in device 300, and some of the features described below may be replaced, modified, or eliminated in other embodiments of device 300.

The present disclosure provides for many different embodiments. An exemplary method includes forming a multilayer stack that includes a first sacrificial layer having a first thickness disposed on a semiconductor extension, semiconductor layers disposed over the first sacrificial layer, and second sacrificial layers having a second thickness interleaving the semiconductor layers. The first thickness is greater than the second thickness. The method further includes removing the first sacrificial layer and the second sacrificial layer from a channel region of the multilayer stack to form a first gap and second gaps, respectively. The first gap is between a respective semiconductor layer and the semiconductor extension, the second gaps are between respective semiconductor layers, the first gap has a first height, and the second gaps have a second height that is greater than the first height. The method further includes forming third sacrificial layers in the first gap and the second gaps. The third sacrificial layers fill a first portion of the first gap and fill the second gaps. The method further includes forming an insulation layer that fills a second portion of the first gap. The insulation layer is disposed between an upper third sacrificial layer and a lower third sacrificial layer that fill the first portion of the first gap. The method further includes removing the third sacrificial layers and the upper third sacrificial layer to form first gate openings and a second gate opening, respectively. The first gate openings are between respective semiconductor layers and the second gate opening is between the respective semiconductor layer and the insulator layer. The method further includes forming a gate stack in the first gate openings and the second gate opening.

In some embodiments, the method further includes further comprising replacing ends of the third sacrificial layers, the upper third sacrificial layer, and the lower third sacrificial layer with inner spacers. In some embodiments, the first sacrificial layer and the second sacrificial layers have a first composition, the third sacrificial layers have a second composition, and the insulation layer has a third composition. The first composition, the second composition, and the third composition are different. In some embodiments, the semiconductor layers are formed of a first semiconductor material, the first sacrificial layer and the second sacrificial layers are formed of a second semiconductor material that is different than the first semiconductor material, the third sacrificial layers are formed of a first dielectric material, and the insulation layer is formed of a second dielectric material that is different than the first dielectric material.

In some embodiments, the method further includes, before removing the first sacrificial layer and the second sacrificial layer from the channel region of the multilayer stack to form the first gap and the second gaps, removing the first sacrificial layer, the second sacrificial layers, and the semiconductor layers to from a first source/drain region and a second source/drain region, respectively, of the multilayer stack. The channel region of the multilayer stack is disposed between a first source/drain recess and a second source/drain recess. In some embodiments, the method further includes, before removing the third sacrificial layers and the upper third sacrificial layer to form the first gate openings and the second gate openings, respectively, forming a first source/drain structure and a second source/drain structure in the first source/drain recess and the second source/drain recess, respectively. In some embodiments, the method further includes partially removing the semiconductor extension. In some embodiments, bottoms of the first source/drain recess and the second source/drain recess may be below a top of the first sacrificial layer and a bottom of the first sacrificial layer. In some embodiments, the method further includes partially removing the semiconductor extension. In such embodiments, bottoms of the first source/drain recess and the second source/drain recess may be below a top of the first sacrificial layer and above a bottom of the first sacrificial layer.

Another exemplary method includes forming a fin-shaped active region over a substrate. The fin-shaped active region includes a first sacrificial layer having a first thickness over a substrate, a first semiconductor layer over the first sacrificial layer, a second sacrificial layer having a second thickness over the first semiconductor layer, and a second semiconductor layer over the second sacrificial layer. The first thickness is greater than the second thickness. The method further includes forming a dummy gate over a first portion of the fin-shaped active region. The method further includes removing a second portion of the fin-shaped active region to form a first source/drain recess and a second source/drain recess. The first portion of the fin-shaped active region is disposed between the first source/drain recess and the second source/drain recess. The method further includes selectively removing the first sacrificial layer and the second sacrificial layer from the first portion of the fin-shaped active region to form a first gap having a first height and a second gap having a second height, respectively. The first gap is between the first semiconductor layer of the fin-shaped active region and the substrate, the second gap is between the first semiconductor layer and the second semiconductor layer of the fin-shaped active region, and the first height is greater than the second height.

The method further includes filling the second gap with a respective third sacrificial layer and the first gap with a respective third sacrificial layer and an insulation layer. The method further includes, after forming a first source/drain structure in the first source/drain recess and a second source/drain structure in the second source/drain recess, selectively removing the dummy gate, the respective third sacrificial layer in the second gap, and a portion of the respective third sacrificial layer in the first gap to form a gate opening. The method further includes forming a gate stack in the gate opening.

In some embodiments, the method further includes replacing ends of the respective third sacrificial layer in the first gap with first inner spacers and ends of the respective third sacrificial layer in the second gap with second inner spacers. In some embodiments, the method further includes forming the insulation layer in the first gap after forming the respective third sacrificial layers and before replacing the ends of the respective third sacrificial layer in the first gap with the first inner spacers and the ends of the respective third sacrificial layer in the second gap with the second inner spacers. In some embodiments, the insulation layer and the respective third sacrificial layers have a first length and replacing the ends of the respective third sacrificial layer in the first gap with the first inner spacers and the ends of the respective third sacrificial layer in the second gap with the second inner spacers provides the respective third sacrificial layers with a second length that is less than the first length.

In some embodiments, filling the first gap with the insulation layer includes depositing an insulation material and selectively removing the insulation material from the first source/drain recess and the second source/drain recess. The insulation material is selectively removed relative to the respective third sacrificial layers, the first semiconductor layer, and the second semiconductor layer. In some embodiments, the respective third sacrificial layer filling the first gap includes a top portion and a bottom portion, the insulation layer is disposed between the top portion and the bottom portion, and the portion of the respective third sacrificial layer in the first gap that is removed to form the gate opening is the top portion.

In some embodiments, first gap is filled with the respective third sacrificial layer and the insulation layer and the second gap is filled with the respective third sacrificial layer by forming oxide layers that fill the second gap and partially fill the first gap and forming a nitride layer that fills a remainder of the first gap. In some embodiments, the method further includes performing a conformal deposition process to form the oxide layers.

An exemplary device structure includes a first semiconductor layer and a second semiconductor layer disposed over a substrate. The first semiconductor layer and the second semiconductor layer extend from a first source/drain structure to a second source/drain structure. An insulation structure is disposed between the first source/drain structure and the second source/drain structure. The insulation structure includes a first insulation layer disposed over the substrate and a second insulation layer disposed over the first insulation layer. The first insulation layer has a first composition and a first length. The second insulation layer has a second composition that is different than the first composition and a second length that is greater than the first length. A gate is disposed over the insulation structure and between the first source/drain structure and the second source/drain structure. The gate includes a first gate portion disposed over the first semiconductor layer, a second gate portion disposed between the first semiconductor layer and the second semiconductor layer, and a third gate portion disposed between the second semiconductor layer and the second insulation layer of the insulation structure. In some embodiments, the first semiconductor layer and the second semiconductor layer have a third length and the third length is substantially the same as the second length of the second insulation layer. In some embodiments, the first gate portion is disposed between a first gate spacer and a second gate spacer, the second gate portion is disposed between a first inner spacer and a second inner spacer, and the third gate portion is disposed between a third inner spacer and a fourth inner spacer. In some embodiments, the first inner spacer and the second inner spacer have a first thickness, the third inner spacer and the fourth inner spacer have a second thickness, and the second thickness is greater than the first thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a multilayer stack that includes a first sacrificial layer having a first thickness disposed on a semiconductor extension, semiconductor layers disposed over the first sacrificial layer, and second sacrificial layers having a second thickness interleaving the semiconductor layers, wherein the first thickness is greater than the second thickness;
removing the first sacrificial layer and the second sacrificial layer from a channel region of the multilayer stack to form a first gap and second gaps, respectively, wherein the first gap is between a respective semiconductor layer and the semiconductor extension, the second gaps are between respective semiconductor layers, the first gap has a first height, and the second gaps have a second height that is greater than the first height;
forming third sacrificial layers in the first gap and the second gaps, wherein the third sacrificial layers fill a first portion of the first gap and fill the second gaps;
forming an insulation layer that fills a second portion of the first gap, wherein the insulation layer is disposed between an upper third sacrificial layer and a lower third sacrificial layer that fill the first portion of the first gap;
removing the third sacrificial layers and the upper third sacrificial layer to form first gate openings and a second gate opening, respectively, wherein the first gate openings are between respective semiconductor layers and the second gate opening is between the respective semiconductor layer and the insulator layer; and
forming a gate stack in the first gate openings and the second gate opening.

2. The method of claim 1, further comprising replacing ends of the third sacrificial layers, the upper third sacrificial layer, and the lower third sacrificial layer with inner spacers.

3. The method of claim 1, wherein the first sacrificial layer and the second sacrificial layers have a first composition, the third sacrificial layers have a second composition, and the insulation layer has a third composition, wherein the first composition, the second composition, and the third composition are different.

4. The method of claim 2, wherein the semiconductor layers are formed of a first semiconductor material, the first sacrificial layer and the second sacrificial layers are formed of a second semiconductor material that is different than the first semiconductor material, the third sacrificial layers are formed of a first dielectric material, and the insulation layer is formed of a second dielectric material that is different than the first dielectric material.

5. The method of claim 1, wherein before removing the first sacrificial layer and the second sacrificial layer from the channel region of the multilayer stack to form the first gap and the second gaps, the method includes:
removing the first sacrificial layer, the second sacrificial layers, and the semiconductor layers to from a first source/drain region and a second source/drain region, respectively, of the multilayer stack, such that the channel region of the multilayer stack is disposed between a first source/drain recess and a second source/drain recess.

6. The method of claim 5, wherein before removing the third sacrificial layers and the upper third sacrificial layer to form the first gate openings and the second gate openings, respectively, the method further includes:
forming a first source/drain structure and a second source/drain structure in the first source/drain recess and the second source/drain recess, respectively.

7. The method of claim 5, further comprising partially removing the semiconductor extension, such that bottoms of the first source/drain recess and the second source/drain recess are below a top of the first sacrificial layer and a bottom of the first sacrificial layer.

8. The method of claim 5, further comprising partially removing the semiconductor extension, such that bottoms of the first source/drain recess and the second source/drain recess are below a top of the first sacrificial layer and above a bottom of the first sacrificial layer.

9. A method comprising:
forming a fin-shaped active region over a substrate, wherein the fin-shaped active region includes a first sacrificial layer having a first thickness over a substrate, a first semiconductor layer over the first sacrificial layer, a second sacrificial layer having a second thickness over the first semiconductor layer, and a second semiconductor layer over the second sacrificial layer, wherein the first thickness is greater than the second thickness;
forming a dummy gate over a first portion of the fin-shaped active region;
removing a second portion of the fin-shaped active region to form a first source/drain recess and a second source/drain recess, wherein the first portion of the fin-shaped active region is disposed between the first source/drain recess and the second source/drain recess;
selectively removing the first sacrificial layer and the second sacrificial layer from the first portion of the fin-shaped active region to form a first gap having a first height and a second gap having a second height, respectively, wherein the first gap is between the first semiconductor layer of the fin-shaped active region and the substrate, the second gap is between the first semiconductor layer and the second semiconductor layer of the fin-shaped active region, and the first height is greater than the second height;
filling the second gap with a respective third sacrificial layer and the first gap with a respective third sacrificial layer and an insulation layer;
after forming a first source/drain structure in the first source/drain recess and a second source/drain structure in the second source/drain recess, selectively removing the dummy gate, the respective third sacrificial layer in the second gap, and a portion of the respective third sacrificial layer in the first gap to form a gate opening; and
forming a gate stack in the gate opening.

10. The method of claim 9, further comprising replacing ends of the respective third sacrificial layer in the first gap with first inner spacers and ends of the respective third sacrificial layer in the second gap with second inner spacers.

11. The method of claim 10, further comprising forming the insulation layer in the first gap after forming the respective third sacrificial layers and before replacing the ends of the respective third sacrificial layer in the first gap with the first inner spacers and the ends of the respective third sacrificial layer in the second gap with the second inner spacers.

12. The method of claim 10, wherein:
the insulation layer and the respective third sacrificial layers have a first length; and
the replacing the ends of the respective third sacrificial layer in the first gap with the first inner spacers and the ends of the respective third sacrificial layer in the second gap with the second inner spacers provides the respective third sacrificial layers with a second length that is less than the first length.

13. The method of claim 9, wherein filling the first gap with the insulation layer includes depositing an insulation material and selectively removing the insulation material from the first source/drain recess and the second source/drain recess, wherein the insulation material is selectively removed relative to the respective third sacrificial layers, the first semiconductor layer, and the second semiconductor layer.

14. The method of claim 9, wherein the respective third sacrificial layer filling the first gap includes a top portion and a bottom portion, the insulation layer is disposed between the top portion and the bottom portion, and the portion of the respective third sacrificial layer in the first gap that is removed to form the gate opening is the top portion.

15. The method of claim 9, wherein the first gap is filled with the respective third sacrificial layer and the insulation layer and the second gap is filled with the respective third sacrificial layer by:
forming oxide layers that fill the second gap and partially fill the first gap; and
forming a nitride layer that fills a remainder of the first gap.

16. The method of claim 15, further comprising performing a conformal deposition process to form the oxide layers.

17. A device structure comprising:
a first semiconductor layer and a second semiconductor layer disposed over a substrate, wherein the first semiconductor layer and the second semiconductor layer extend from a first source/drain structure to a second source/drain structure;
an insulation structure disposed between the first source/drain structure and the second source/drain structure, wherein the insulation structure includes:
a first insulation layer disposed over the substrate, wherein the first insulation layer has a first composition and a first length, and
a second insulation layer disposed over the first insulation layer, wherein the second insulation layer has a second composition that is different than the first composition and a second length that is greater than the first length; and
a gate disposed over the insulation structure and between the first source/drain structure and the second source/drain structure, wherein the gate includes a first gate portion disposed over the first semiconductor layer, a second gate portion disposed between the first semiconductor layer and the second semiconductor layer, and a third gate portion disposed between the second semiconductor layer and the second insulation layer of the insulation structure.

18. The device structure of claim 17, wherein the first semiconductor layer and the second semiconductor layer have a third length and the third length is substantially the same as the second length of the second insulation layer.

19. The device structure of claim 17, wherein the first gate portion is disposed between a first gate spacer and a second gate spacer, the second gate portion is disposed between a first inner spacer and a second inner spacer, and the third gate portion is disposed between a third inner spacer and a fourth inner spacer.

20. The device structure of claim 19, wherein the first inner spacer and the second inner spacer have a first thickness, the third inner spacer and the fourth inner spacer have a second thickness, and the second thickness is greater than the first thickness.
